(19) United States
(12) Patent Application Publication
(10) Pub. No.: US 2025/0095951 A1
(43) Pub. Date: Mar. 20, 2025

(54) ELECTRONIC COMPONENT AND CHARGED PARTICLE BEAM IRRADIATION APPARATUS

(71) Applicants: KABUSHIKI KAISHA TOSHIBA, Tokyo (JP); NuFlare Technology, Inc., Yokohama-shi (JP)

(72) Inventors: Kazuyuki HIGASHI, Yokohama (JP); Kazumichi TSUMURA, Shinagawa (JP); Tomohiro SAITO, Yokohama (JP); Takashi YODA, Hino (JP); Munehiro OGASAWARA, Hiratsuka (JP); Kenji HIRAKAWA, Narashino (JP); Masayuki IWASE, Yokohama (JP)

(73) Assignees: KABUSHIKI KAISHA TOSHIBA, Tokyo (JP); NuFlare Technology, Inc., Yokohama-shi (JP)

(21) Appl. No.: 18/595,532

(22) Filed: Mar. 5, 2024

(30) Foreign Application Priority Data
Sep. 19, 2023 (JP) 2023-151758

(51) Int. Cl. H01J 37/147; H01J 37/04; H01J 37/317; H01L 23/00; H01L 23/58

(52) U.S. Cl. CPC H01J 37/1472; H01J 37/045; H01J 37/3174; H01L 23/585; H01L 24/13; H01L 24/16; H01J 2237/0435; H01L 2224/13144; H01L 2224/13147; H01L 2224/16265

(57) ABSTRACT

An electronic component according to an embodiment includes: a first substrate including first through holes, a first substrate surface and a second substrate surface; first electrodes provided on each of the first through holes, and including a first end and a second end; second electrodes provided on each of the first through holes, facing each of the first electrodes, and including a third end facing the first end and a fourth end facing the second end; third electrodes connected to the first end and extending toward the third end; fourth electrodes connected to the second end and extending toward the fourth end; fifth electrodes connected to the third end, provided separately from each of the third electrodes and extending toward the first end; sixth electrodes connected to the fourth end, provided separately from each of the fourth electrodes and extending toward the second end.

### CROSS-REFERENCE TO RELATED APPLICATION

This application is based upon and claims the benefit of priority from Japanese Patent Application No. 2023-151758, filed on Sep. 19, 2023, the entire contents of which are incorporated herein by reference.

### FIELD

Embodiments described herein relate generally to an electronic component and a charged particle beam irradiation apparatus.

### BACKGROUND

Lithography technology is a process technology that is responsible for the development of microfabrication of a semiconductor device. Lithography technology is a very important process technology. In recent years, with the increase in the integration of LSI, the circuit line width required for the semiconductor device have been miniaturized year by year. The electron beam writing technology has an inherently excellent resolution. Therefore, writing of a mask pattern to a mask blank using the electron beam is performed.

An irradiation device using multi electron beams (the multiple beams) can significantly improve the throughput as compared with a single electron beam. For example, in a multiple beams-based writing apparatus, the multiple beams are formed by passing the electron beam emitted from an electron gun through a shaping aperture having a plurality of holes. The respective electron beams constituting the multiple beams are blanking-controlled by a blanking aperture array. The electron beam that is not deflected by the blanking aperture array is irradiated onto a target object such as the mask blank. On the other hand, the electron beam deflected by the blanking aperture array is shielded (blanking).

The blanking aperture array has through holes through which each electron beam passes. A pair of electrodes is provided around the through hole. An electric field (deflection electric field) for deflecting the electron beam is generated between the pair of electrodes.

### BRIEF DESCRIPTION OF THE DRAWINGS

FIG. 1 is a schematic cross-sectional view of the electron beam writing apparatus of a first embodiment.

FIGS. 2A-B are schematic diagrams of a main part of an electronic component of the first embodiment.

FIGS. 3A-B are schematic cross-sectional views of a main part of the electronic component according to another aspect of the first embodiment.

FIG. 4 is a schematic cross-sectional view showing a process for manufacturing the electronic component according to the first embodiment.

FIG. 5 is a schematic cross-sectional view showing the process for manufacturing the electronic component according to the first embodiment.

FIG. 6 is a schematic cross-sectional view showing the process for manufacturing the electronic component according to the first embodiment.

FIG. 7 is a schematic cross-sectional view showing the process for manufacturing the electronic component according to the first embodiment.

FIG. 8 is a graph showing a change in the average electric field strength and a change in the variation of the electric field strength due to the difference in the shapes of the electrodes.

FIG. 9 is a schematic top view showing an electrode according to structure A described in FIG. 8, which is a comparative example of the first embodiment.

FIG. 10 is a schematic top view showing an electrode according to structure B described in FIG. 8, which is a comparative example of the first embodiment.

FIG. 11 is a schematic top view showing an electrode according to structure C described in FIG. 8, which is a comparative example of the first embodiment.

FIG. 12 is a schematic top view showing an electrode according to structure D described in FIG. 8, which is the electrode according to the first embodiment.

FIG. 13 is a graph showing the change in the average electric field strength due to the difference in the length of the first electrode and the length of the second electrode.

FIG. 14 is a graph showing the change in the variation of the electric field strength due to the difference in the length of the first electrode and the length of the second electrode.

FIG. 15 is a schematic top view showing an example of structure E shown in FIG. 13 and FIG. 14, which shows an example of an electrode according to structure E1, which is a comparative example of the first embodiment.

FIG. 16 is a schematic top view showing an example of the structure E shown in FIG. 13 and FIG. 14, which shows an example of an electrode according to structure E2, which is an electrode according to the first embodiment.

FIG. 17 is a schematic top view showing an example of the structure E shown in FIG. 13 and FIG. 14, which shows an example of an electrode according to structure E3, which is an electrode according to the first embodiment.

FIG. 18 is a schematic top view showing an example of structure F shown in FIG. 13 and FIG. 14, which shows an example of an electrode according to structure F1, which is a comparative example of the first embodiment.

FIG. 19 is a schematic top view showing an example of the structure F shown in FIG. 13 and FIG. 14, which shows an example of an electrode according to structure F2, which is a comparative example of the first embodiment.

FIG. 20 is a schematic top view showing an example of structure F shown in FIG. 13 and FIG. 14, which shows an example of an electrode according to structure F3, which is a comparative example of the first embodiment.

FIG. 21 is a graph showing the relationship between the ratio of the distance between the third electrode and the fifth electrode d₁ to the distance between the first electrode and the second electrode d₂ (d₁/d₂) and the ratio of the distance between the fourth electrode and the sixth electrode d₃ to the distance between the first electrode and the second electrode d₂ (d₃/d₂), and the average electric field strength.

FIG. 22 is a graph showing the relationship between the ratio of the distance between the third electrode and the fifth electrode d₁ to the distance between the first electrode and the second electrode d₂ (d₁/d₂) and the ratio of the distance between the fourth electrode and the sixth electrode d₃ to the distance between the first electrode and the second electrode d₂ ((d₃/d₂)), and the variation of the electric field strength.

FIG. 23 is a schematic top view of an electrode of the first embodiment whose ratio of the distance between the third electrode and the fifth electrode d₁ to the distance between the first electrode and the second electrode d₂ (d₁/d₂) and whose ratio of the distance between the fourth electrode and the sixth electrode d₃ to the distance between the first electrode and the second electrode d₂ (d₃/d₂) are 0.09.

FIG. 24 is a schematic top view of an electrode of the first embodiment whose ratio of the distance between the third electrode and the fifth electrode d₁ to the distance between the first electrode and the second electrode d₂ (d₁/d₂) and whose ratio of the distance between the fourth electrode and sixth electrode d₃ to the distance between the first electrode and the second electrode d₂ (d₃/d₂) are 0.27.

FIG. 25 is a schematic top view of an electrode of the first embodiment whose ratio of the distance between the third electrode and the fifth electrode d₁ to the distance between the first electrode and the second electrode d₂ (d₁/d₂) and whose ratio of the distance between the fourth electrode and sixth electrode d₃ to the distance between the first electrode and the second electrode d₂ (d₃/d₂) are 0.45.

FIG. 26 is a schematic top view of an electrode of the comparative example of the first embodiment whose ratio of the distance between the third electrode and the fifth electrode d₁ to the distance between the first electrode and the second electrode d₂ (d₁/d₂) and whose ratio of the distance between the fourth electrode and sixth electrode d₃ to the distance between the first electrode and the second electrode d₂ (d₃/d₂) are 0.63.

FIG. 27 is a schematic top view of an electrode of the comparative example of the first embodiment whose ratio of the distance between the third electrode and the fifth electrode d₁ to the distance between the first electrode and the second electrode d₂ (d₁/d₂) and whose ratio of the distance between the fourth electrode and sixth electrode d₃ to the distance between the first electrode and the second electrode d₂ (d₃/d₂) are 0.82.

FIG. 28 is a schematic top view of electrodes without the third electrode, the fourth electrode, the fifth electrode and the sixth electrode.

FIG. 29 is a graph showing the relationship between the difference of the position of the end of the third electrode, the difference of the position of the end of the fourth electrode, the difference of the position of the end of the fifth electrode, and the difference of the position of the end of the sixth electrode, and the average electric field strength and the variation of the electric field strength.

FIG. 30 is a schematic top view of structure G of FIG. 29, which is a comparative embodiment of the first embodiment.

FIG. 31 is a schematic top view of an electrode of structure H of FIG. 29, which is the electrode of the first embodiment.

FIG. 32 is a schematic top view of an electrode of structure I of FIG. 29, which is the electrode of the first embodiment.

FIG. 33 is a schematic top view of an electrode of structure J of FIG. 29, which is the electrode of the first embodiment.

FIG. 34 is a schematic top view of an electrode of structure K of FIG. 29, which is the electrode of the comparative example of the first embodiment.

FIG. 35 is a graph showing the relationship between the length of the electrode in the Y-direction, and the average electric field strength and the variation of the electric field strength.

FIG. 36 is a schematic top view of an electrode of structure L of FIG. 35, which is the electrode of the first embodiment.

FIG. 37 is a schematic top view of an electrode of structure M of FIG. 35, which is the electrode of the first embodiment.

FIG. 38 is a schematic top view of an electrode of structure N of FIG. 35, which is the electrode of the first embodiment.

FIG. 39 is a graph showing the average electric field strength and the variation of the electric field strength depending on the difference of the structure of the first electrode and the third electrode in the vicinity of the first end, the structure of the first electrode and the fourth electrode in the vicinity of the second end, the structure of the second electrode and the fifth electrode in the vicinity of the third end, and the structure of the second electrode and the sixth electrode in the vicinity of the fourth end.

FIG. 40 is a schematic top view of an electrode of structure O of FIG. 39, which is the electrode of the first embodiment.

FIG. 41 is a schematic top view of an electrode of structure P of FIG. 39, which is the electrode of the first embodiment.

FIG. 42 is a schematic top view of an electrode of structure Q of FIG. 39, which is the electrode of the first embodiment.

FIGS. 43A-B are schematic top views of a main part of the electronic component of a second embodiment.

FIG. 44A-B are schematic top views of a main part of the electronic component of a third embodiment.

### DETAILED DESCRIPTION

Hereinafter, embodiments will be described with reference to the drawings. In the drawings, the same or similar parts are denoted by the same or similar reference numerals.

In the present specification, the same or similar members are denoted by the same reference numerals, and redundant description thereof may be omitted.

In the present specification, in order to show the positional relationship of the components and the like, the upward direction of the drawings is described as “up”, and the downward direction of the drawings is described as “down”. In the present specification, the terms “upper” and “lower” do not necessarily indicate the relationship with the direction of gravity.

Hereinafter, a configuration using an electron beam (the electron beam) will be described as an example of the charged particle beam (charged particle beam). However, the charged particle beam is not limited to an electron beam. The charged particle beam can be the ion beam.

### First Embodiment

The electronic component of the present embodiment includes: a first substrate including a first substrate surface, a second substrate surface provided on the opposite side of the first substrate surface, and a plurality of first through holes, each of the first through holes through which each of multiple charged particle beams passes; a plurality of first electrodes, each of the first electrodes being provided on each of the first through holes, and each of the first electrodes including a first end and a second end; a plurality of second electrodes, each of the second electrodes being provided on each of the first through holes, being arranged to face each of the first electrodes, and including a third end facing the first end and a fourth end facing the second end; a plurality of third electrodes, each of the third electrodes being connected to the first end and extending toward the third end; a plurality of fourth electrodes, each of the fourth electrodes being connected to the second end and extending toward the fourth end; a plurality of fifth electrodes, each of the fifth electrodes being connected to the third end, each of the fifth electrodes being provided separately from each of the third electrodes, and each of the fifth electrodes extending toward the first end; and a plurality of sixth electrodes, each of the sixth electrodes being connected to the fourth end, each of the sixth electrodes being provided separately from each of the fourth electrodes, and each of the sixth electrodes extending toward the second end.

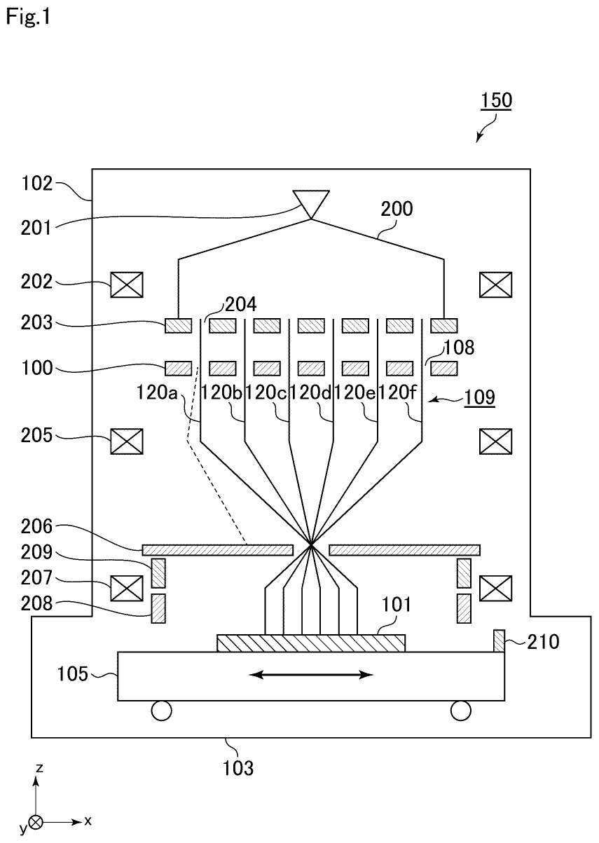

FIG. 1 is the schematic cross-sectional view of the electron beam writing apparatus 150 of the first embodiment.

The electronic component 100 of the present embodiment is used, for example, as the blanking aperture array (the deflector) of the electron beam writing apparatus 150. Note that the use of the electronic component 100 is not limited to this.

The electron beam writing apparatus 150 includes the electron optical column 102 (multi electron beam column) and the writing chamber 103. Disposed within the electron optical column 102 are the electron gun 201, the illumination lens 202, the shaping aperture array 203, the electronic component 100, the reduction lens 205, the limiting aperture plate member 206, the objective lens 207, the main deflector 208, and the secondary deflector 209.

The electron gun 201 emits the electron beam 200. The electron gun 201 is an example of the irradiation source.

Here, the X-axis, the Y-axis that intersects perpendicularly to the X-axis, and the Z-axis that intersects perpendicularly to the X-axis and the Y-axis are defined. It is assumed that the electron gun 201 emits the electron beam 200 oppositely to the Z-axis. Further, it is assumed that a target object 101 is disposed in a plane parallel to XY plane.

The electron beam 200 emitted from the electron gun 201 illuminates the shaping aperture array 203 substantially perpendicularly by the illumination lens 202. The multiple beams 109 are formed by passing the electron beam 200 through the openings of the shaping aperture array 203. The multiple beams 109 have the electron beam 120a, 120b, 120c, 120d, 120e and a 120f. The shape of each of the electron beams 120 reflects the shape of the opening of the shaping aperture array 203. Each electron beam 120 has, for example, a rectangular shape. Here, the number of the openings 204 of the shaping aperture array 203 illustrated in FIG. 1 is six. However, the number of the openings 204 of the shaping aperture array 203 is not limited to six. The number of the multiple beams 109 formed by the shaping aperture array 203 illustrated in FIG. 1 is six. However, the number of the multiple beams 109 formed by the shaping aperture array 203 is not limited to six.

The electronic component 100 is provided below the shaping aperture array 203. The position of the electron beam 120 deflected by the electronic component 100 deviates from the central bore of the limiting aperture plate member 206. The electron beam 120 deflected by the electronic component 100 is shielded by the limiting aperture plate member 206. On the other hand, the electron beam 120 that has not been deflected by the electronic component 100 passes through the central bore of the limiting aperture plate member 206. In this way, the on/off of the electron beam is controlled. Here, the number of the openings 108 of the electronic component 100 illustrated in FIG. 1 is six. However, the number of the openings 108 of the electronic component 100 is not limited to six.

The focus of the electron beam 120 passing through the limiting aperture plate member 206 is appropriately adjusted by the objective lens 207. After that, the electron beam 120 that has passed through the limiting aperture plate member 206 becomes a patterned image having a desired reduction ratio. Thereafter, the electron beams 120 that have passed through the limiting aperture plate member 206 are collectively deflected by the main deflector 208 and the secondary deflector 209. Thereafter, the electron beam 120 that has passed through the limiting aperture plate member 206 is irradiated to the respective irradiation position on the target object 101 placed on the XY stage 105. In the XY stage 105, the mirror 210 for measuring the position of the XY stage 105 is disposed.

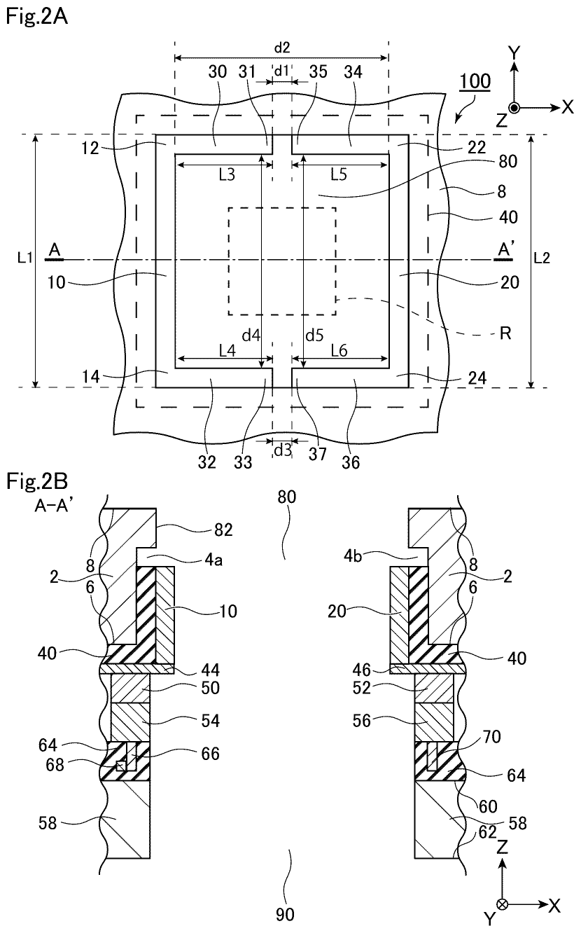

FIGS. 2A-B are schematic diagrams of the main part of the electronic component of the present embodiment. FIG. 2A is the schematic top view of the main part of the electronic component 100 of the present embodiment. FIG. 2B is the schematic cross-sectional view of the electronic component 100 of the main part of the present embodiment in A-A′ cross section indicated by FIG. 2A.

The first substrate 2 is, for example, the semiconductor substrate. The first substrate 2 is, for example, the Si (silicon) substrate. However, the first substrate 2 is not limited to the semiconductor substrate. For example, as the first substrate 2, other substrate such as the insulating substrate can be preferably used. Here, the insulating substrate is, for example, the ceramic substrate. The insulating substrate is, for example, the glass epoxy substrate containing the glass fibers and the epoxy resin.

The first substrate 2 has the first substrate surface 6 and the second substrate surface 8 facing the first substrate surface 6. In FIGS. 2A-B, the first substrate surface 6 is shown to be positioned below the second substrate surface 8.

The first substrate 2 has a plurality of first through holes 80. Each of the electron beams 120 included in the multiple beams 109 passes through each of the plurality of first through holes 80.

In the electronic component 100 shown in FIGS. 2A-B, the plurality of first through holes 80 in a plane parallel to the XY plane have squares. However, the shapes of the plurality of first through holes 80 in the plane parallel to the XY plane are not limited to squares.

The plurality of first electrodes 10 are respectively provided in the plurality of first through holes 80. In the electronic component 100 shown in FIGS. 2A-B, the plurality of first electrodes 10 are respectively provided in the plurality of first through holes 80. The first electrode 10 includes the first end 12 and the second end 14. The first electrode 10 extends in the Y-direction. The first electrode 10 is provided parallel to the Y-direction. The shapes of the plurality of first electrodes 10 when viewed from above are, for example, rectangular shapes.

The plurality of second electrodes 20 are respectively provided in the plurality of first through holes 80. In the electronic component 100 shown in FIGS. 2A-B, the plurality of second electrodes 20 are respectively provided in the plurality of first through holes 80. The second electrode 20 has the third end 22 facing the first end 12 and the fourth end 24 facing the second end 14. The second electrode 20 faces the first electrode 10. The plurality of second electrodes 20 extends in the Y-direction, respectively. The plurality of second electrodes 20 are provided parallel to the Y-direction, respectively. The shapes of the plurality of second electrodes 20 when viewed from above are, for example, rectangular shapes, respectively.

The plurality of third electrodes 30 are provided in the first through holes 80, respectively. In the electronic component 100 shown in FIGS. 2A-B, the plurality of third electrodes 30 are provided in the plurality of first through holes 80, respectively. The third electro de 30 is connected to the first end 12. The third electrode 30 extends toward the third end 22. The third electrode 30 extends in the X-direction. The third electrodes 30 are provided parallel to the X-direction, respectively. The shapes of the plurality of third electrodes 30 when viewed from above are, for example, rectangular shapes, respectively.

The plurality of fourth electrodes 32 are provided in the plurality of first through holes 80, respectively. In the electronic component 100 shown in FIGS. 2A-B, the plurality of fourth electrodes 32 are provided in the plurality of first through holes 80, respectively. The fourth electrode 32 is connected to the second end 14. The fourth electrode 32 extends toward the fourth end 24. The fourth electrode 32 extends in the X-direction. The fourth electrodes 32 are provided parallel to the X-direction, respectively. The shapes of the plurality of fourth electrodes 32 when viewed from above are, for example, rectangular shapes, respectively.

The plurality of fifth electrodes 34 are provided in the plurality of first through holes 80, respectively. In the electronic component 100 shown in FIG. 2, the plurality of fifth electrodes 34 are provided in the plurality of first through holes 80, respectively. The fifth electrode 34 is connected to the third end 22. The fifth electrode 34 extends toward the first end 12. The fifth electrode 34 extends in the X-direction. The fifth electrode 34 is provided parallel to the X-direction. The fifth electrode 34 is provided separately from the third electrode 30. The shapes of the plurality of fifth electrodes 34 when viewed from above are, for example, rectangular shapes, respectively.

The plurality of sixth electrodes 36 are provided in the plurality of first through holes 80, respectively. In the electronic component 100 shown in FIG. 2, the plurality of sixth electrodes 36 are provided in the plurality of first through holes 80, respectively. The sixth electrode 36 is connected to the fourth end 24. The sixth electrode 36 extends toward the second end 14. The sixth electrode 36 extends in the X-direction. The sixth electrode 36 is provided parallel to the X-direction. The sixth electrode 36 is provided separately from the fifth electrode 34. The shapes of the plurality of sixth electrodes 36 when viewed from above are, for example, rectangular shapes, respectively.

The distance d₁ between the third electrode 30 and the fifth electrode 34 is preferably 10% or more and 40% or less of the distance d₂ between the first electrode 10 and the second electrode 20.

The distance d₃ between the fourth electrode 32 and the sixth electrode 36 is preferably 10% or more and 40% or less of the distance d₂ between the first electrode 10 and the second electrode 20.

The length L₁ of the first electrode 10 and the length L₂ of the second electrode 20 are preferably equal.

The length L₃ of the third electrode 30 and the length L₅ of the fifth electrode 34 are preferably equal.

The length L₄ of the fourth electrode 32 and the length L₆ of the sixth electrode 36 are preferably equal.

It is preferable that the distance d₄ between the fifth end 31 of the third electrode 30 facing the fifth electrode 34 and the sixth end 33 of the fourth electrode 32 facing the sixth electrode 36 is equal to the distance d₅ between the seventh end 35 of the fifth electrode 34 facing the third electrode 30 and the eighth end 37 of the sixth electrode 36 facing the fourth electrode 32.

The first insulating film (an example of an insulating film) 40 is provided between the first substrate 2 and the first electrode 10, the second electrode 20, the third electrode 30, the fourth electrode 32, the fifth electrode 34, and the sixth electrode 36, in the plurality of first through holes 80, respectively. Further, the insulating film 40 is provided in contact with the first substrate surface 6. The insulating film 40 provided in each of the plurality of first through holes 80 is continuous with the insulating film 40 provided in contact with the first substrate surface 6. However, the shape of the insulating film 40 is not limited to the above. The insulating film 40 includes, for example, SiOx (silicon oxide).

The circuit board (an example of a second substrate) 58 includes the third substrate surface 60 and the fourth substrate surface 62. The third substrate surface 60 is provided to face the first substrate surface 6. The circuit board 58 is, for example, a silicon substrate. However, the circuit board 58 is not limited to a silicon substrate. The circuit board 58 includes the plurality of second through holes 90.

The pair of the first through hole 80 and the second through hole 90 corresponds to the opening 108 (FIG. 1). The first through holes 80 are provided above the second through holes 90, respectively.

In FIG. 2, one first through hole 80 among the plurality of first through holes 80 included in the first substrate 2 is illustrated. In addition, in FIG. 2, one second through hole 90 among the plurality of second through holes 90 included in the circuit board 58 is illustrated.

The second insulating film 64 is provided on the third substrate surface 60 of the circuit board 58. The second insulating film 64 includes, for example, silicon oxide. However, the second insulating film 64 may be a stacked film of a film containing silicon oxide and a film containing SiNx (silicon nitride).

The plurality of first plate electrodes 44 are provided below the first electrodes 10 and below the insulating films 40 in contact with the first electrodes 10, respectively. The plurality of first plate electrodes 44 are electrically and continuously connected to the first electrodes 10, respectively.

The plurality of first junction electrodes 50 are provided below the plurality of first plate electrodes 44, respectively. The plurality of first junction electrodes 50 are electrically connected to the plurality of first plate electrodes 44, respectively. The plurality of first junction electrodes 50 are provided on the first substrate surface 6 via the insulating films 40, respectively.

The plurality of second plate electrodes 46 are provided below the second electrodes 20 and below the insulating films 40 in contact with the second electro des 20, respectively. The plurality of second plate electrodes 46 are electrically and continuously connected to the second electrodes 20.

The plurality of second junction electrodes 52 are provided below the plurality of second plate electrodes 46, respectively. The plurality of second junction electrodes 52 are electrically connected to the plurality of second plate electrodes 46, respectively. The plurality of second junction electrodes 52 are provided on the first substrate surface 6 via the insulating films 40, respectively.

The plurality of third junction electrodes 54 are provided below the plurality of first junction electrodes 50, respectively. The plurality of third junction electrodes 54 are electrically connected to the plurality of first junction electrodes 50, respectively. The plurality of third junction electrodes 54 are provided on the third substrate surface 60 via the second insulating films 64, respectively.

The plurality of fourth junction electrodes 56 are provided below the plurality of second junction electrodes 52, respectively. The plurality of fourth junction electrodes 56 are electrically connected to the plurality of second junction electrodes 52, respectively. The plurality of fourth junction electrodes 56 are provided on the third substrate surface 60 via the second insulating films 64, respectively.

The length of the plurality of first junction electrodes 50 in the Z-direction, the length of the plurality of second junction electrodes 52 in the Z-direction, the length of the plurality of third junction electrodes 54 in the Z-direction, and the length of the plurality of fourth junction electrodes 56 in the Z-direction are, for example, about 2 μm.

In the vicinity of the second substrate surface 8, the side surfaces of the plurality of first through holes 80 may have exposed portions (parts where part of the first substrate 2 are exposed) 82. Note that the side surfaces of the plurality of first through holes 80 may not have the exposed portion 82. When the first substrate 2 is a semiconductor substrate such as a Si (silicon) substrate, it is preferable that the side surfaces of the plurality of first through holes 80 are exposed and have exposed portions (parts where parts of the first substrate 2 are exposed) 82. For example, as compared with the case where the insulating film 40 is provided, since the side surfaces of the plurality of first through holes 80 have the exposed portions 82, a part other than the electrode of the first through holes 80 in the vicinity of the second substrate surface 8 can be kept at the substrate potential. Thus, the deflection of the electrons due to electrostatic charge can be suppressed.

The first substrate 2 includes a plurality of concavities 4. Each of the concavities 4 is provided on a side surface of the first through hole 80 between the insulating film 40 and the second substrate surface 8 so as to surround the first through hole 80. In the vicinity of the second substrate surface 8, when the side surfaces of the plurality of the first through holes 80 include the exposed portions 82, the concavity 4 is provided on the side surface of the first through hole 80 between the insulating film 40 and the exposed portion 82 so as to surround the first through hole 80. By providing the concavity 4, it is possible to prevent the insulating film 40 from being exposed in a plane parallel to XY plane including the concavity 4. Thus, the deflection of electrons due to electrostatic charge of the insulating film 40 can be suppressed. Note that the plurality of concavities 4 may not be provided.

The plurality of control circuits 68 are provided in the second insulating film 64 below the first electrode. The control circuit 68 is, for example, a CMOS (Complimentary Metal-Oxide-Semiconductor) circuit. The control circuit 68 has a function of applying a predetermined voltage of, for example, about 5V to each of the plurality of first electrodes 10 via the wiring 66 in the second insulating film 64, the third junction electrode 54, the first junction electrode 50, and the first plate electrode 44.

The wiring 70 is provided in the second insulating film 64. The wiring 70 is connected to the fourth junction electrode 56. The wiring 70 grounds the second electrode 20 via the second plate electrode 46, the second junction electrode 52, and the fourth junction electrode 56.

The first substrate 2 and the circuit board 58 may be grounded.

The plurality of first electrodes 10, the plurality of second electrodes 20, the plurality of third electrodes 30, the plurality of fourth electrodes 32, the plurality of fifth electrodes 34, and the plurality of sixth electrodes 36 include, for example, metal nitride such as TiN (titanium nitride), or metal such as W (tungsten).

The plurality of first plate electrodes 44, the plurality of second plate electrodes 46, the plurality of first junction electrodes 50, the plurality of second junction electrodes 52, the plurality of third junction electrodes 54, the plurality of fourth junction electrodes 56, the wirings 66, and the wirings 70 include, for example, metal such as Au (gold) or Cu (copper).

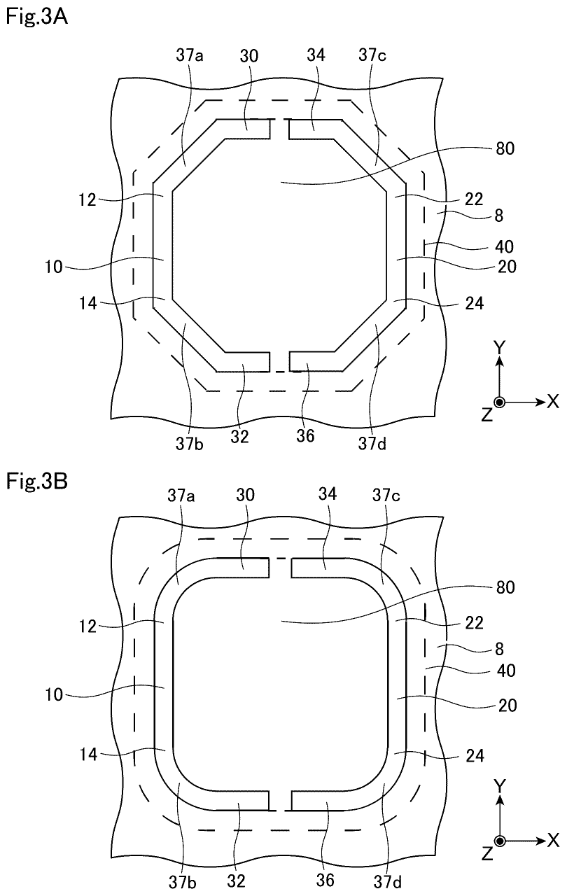

FIGS. 3A-B are schematic cross-sectional views of the main part of the electronic component 100a and 100b according to another aspect of the present embodiment.

The shape of the first through hole 80 and the shape of the insulating film 40 when viewed from above may be, for example, an octagonal shape as shown in FIG. 3A. Alternatively, it does not matter if it is more polygonal than that. In addition, the shape of the first through hole 80 and the shape of the insulating film 40 when viewed from above may be, for example, a square shape in which corners are chamfered (R-chamfered), as shown in FIG. 3B. Further, in the cases shown in FIG. 3A and FIG. 3B, the first connecting electrode 37a for connecting the first end 12 and the third electrode 30, the second connecting electrode 37b for connecting the second end 14 and the fourth electrode 32, the third connecting electrode 37c for connecting the third end 22 and the fifth electrode 34, and the fourth connecting electrode 37d for connecting the fourth end 24 and the sixth electrode 36 may be provided.

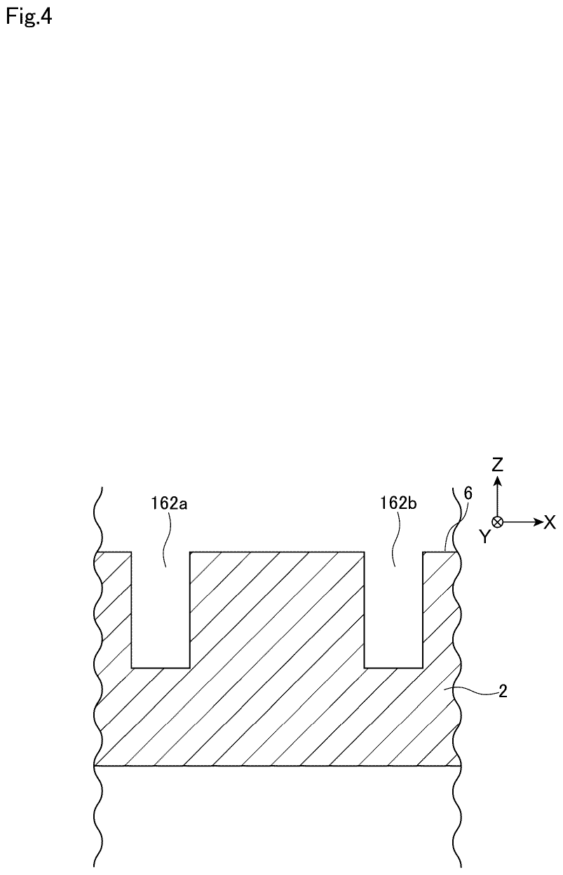

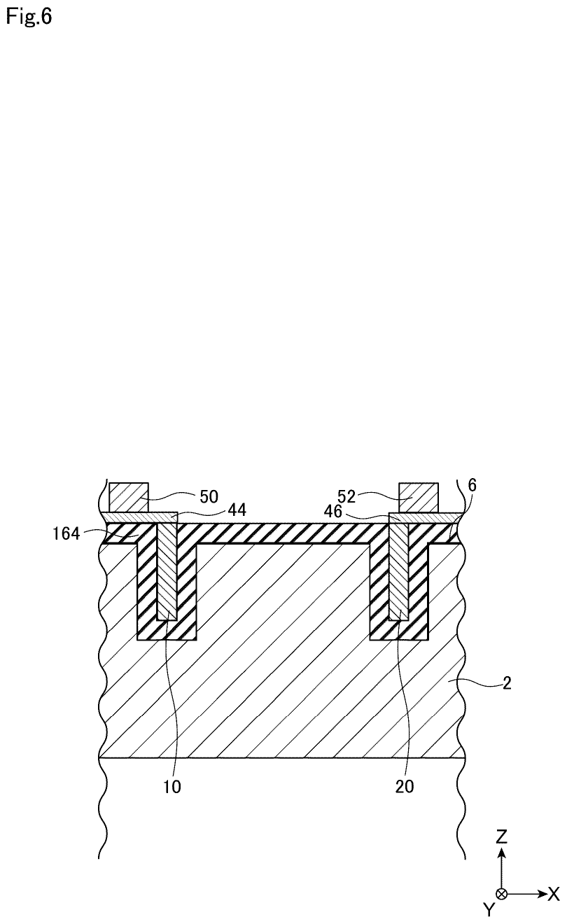

FIG. 4 to FIG. 7 are schematic cross-sectional views showing a process for manufacturing the electronic component 100 of the present embodiment.

First, on the first substrate surface 6 of the first substrate 2, a groove 162 extending in the Y-direction is formed by, e.g., RIE (Reactive Ion Etching). The width of the groove 162 is, for example, 2 μm or more and 6 μm or less. The depth of the groove 162 is, for example, about 60 μm (FIG. 4). In FIG. 4, the groove 162a and the groove 162b are illustrated.

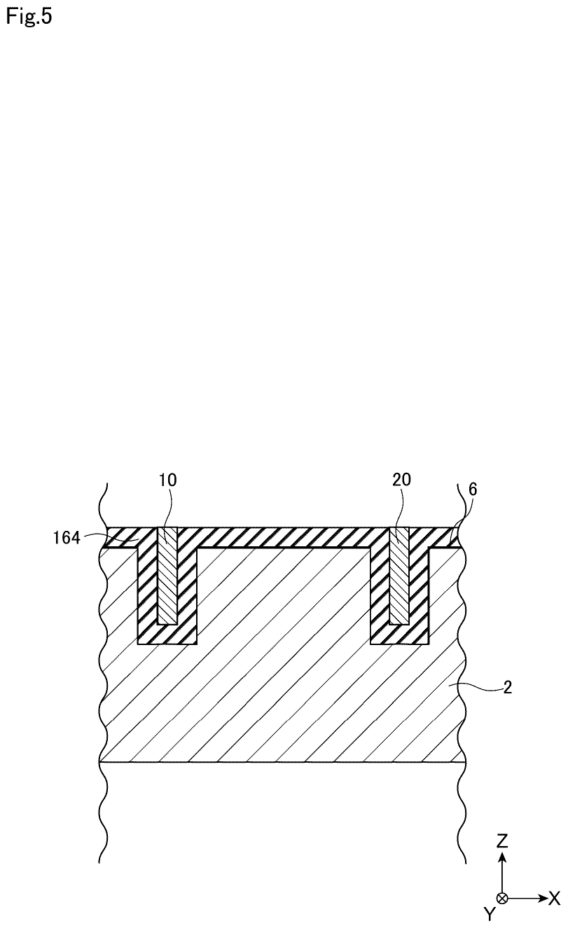

Next, an insulating film 164 containing, for example, silicon oxide is formed on the inside of the groove 162a, on the inside of the groove 162b, and on the first substrate surface 6 by, for example, CVD (Chemical Vapor Deposition). Next, on the insulating film 164 formed in the groove 162a and the groove 162b, the first electrode 10 and the second electrode 20 including metal nitride such as TiN (titanium nitride) or metal such as W (tungsten) are formed by, for example, CVD. Thereafter, the upper surfaces of the insulating film 164, the first electrode 10, and the second electrode 20 are planarized by, for example, etch-back (FIG. 5).

Next, the first plate electrode 44 including, for example, gold, is formed over the first electrode 10 and over the insulating film 164 provided on the upper left part of the first electrode 10. In addition, the second plate electrode 46 including, for example, gold, is formed over the second electrode 20 and over the insulating film 164 on the upper right part of the second electrode 20. Note that, for example, a plating method and a photolithography method are used for forming the first plate electrode 44 and the second plate electrode 46.

Next, the first junction electrode 50 containing, for example, gold, is formed on the first plate electrode 44. Further, the second junction electrode 52 containing, for example, gold, is formed on the second plate 46. Note that, for example, a plating method and a photolithography method are used for forming the first junction electrode 50 and the second junction electrode 52.

Next, for example, the surface of the first substrate 2 facing the first substrate surface 6 is polished. Thus, the first substrate 2 is thinned. The second substrate surface 8 is formed on a surface of the first substrate 2 facing the first substrate surface 6.

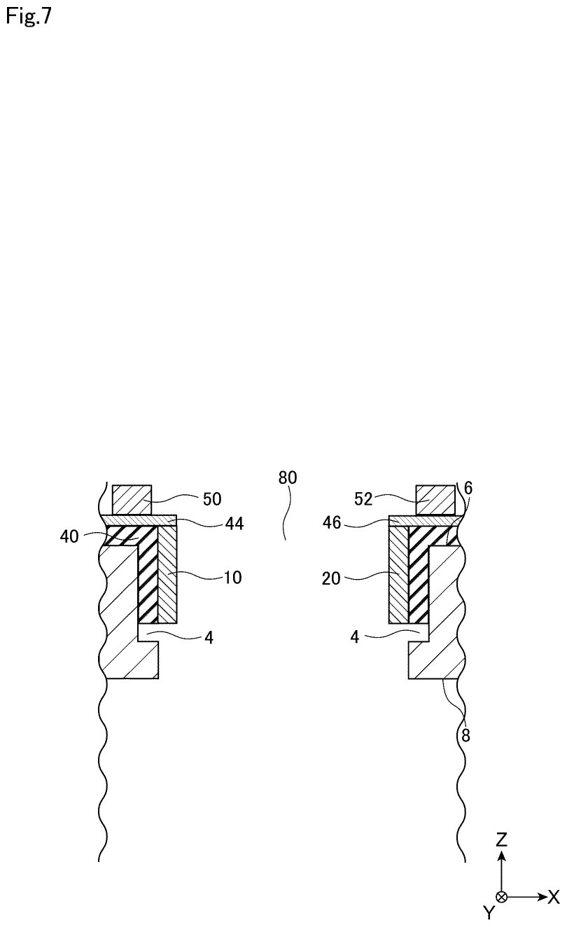

Next, the first substrate 2 between the first electrode 10 and the second electrode 20 is removed, e.g., by RIE, to form the first through hole 80. Next, the insulating film 164 provided on the right side surface of the first electrode and under the first electrode 10 and the insulating film 164 provided on the left side surface of the second electrode 20 and under the second electrode 20 are removed by, for example, Vapor HF (hydrofluoric acid in vapor form). By removing the insulating film 164, the insulating film 40 is formed. The insulating film 40 is removed isotropically by Vapor HF. Therefore, the concavity 4 surrounding the first through hole 80 is formed on the side surface of the first through hole 80 below the insulating film 40 (FIG. 7).

Next, the third junction electrode 54 of the circuit board 58 including the second through hole 90, the second insulating film 64, the wiring 66, the control circuit 68, the wiring 70, the third junction electrode 54, and the fourth junction electrode 56 is bonded to the first junction electrode 50. Further, the fourth junction electrode 56 is bonded to the second junction electrode 52. As a result, the electronic component 100 of the present embodiment is obtained.

Next, the operation and effect of the electronic component 100 of the present embodiment will be described.

When the electron beam is deflected by using electrodes formed of gold, it is difficult to miniaturize the distance between the electrodes because the electrode shape controllability is not good.

In addition, in order to increase the amount of deflection of the electron beam passing through the blanking aperture array, it is conceivable to increase the height of the electrode provided on the blanking aperture array. This is to deflect the electron beam over as long a distance as possible by increasing the height of the electrode and by increasing the distance of the Z-direction electrode. However, in the case of electrodes formed of gold, since the electrode shape controllability is not good, it is difficult to increase the height of the electrode.

In addition, since it is difficult to control the distance between the electrodes and the height of the electrodes, the strength of the respective deflecting electric fields applied to the plurality of electron beams passing through the blanking aperture array varies.

Therefore, the electronic component of the present embodiment including a first substrate including a first substrate surface, a second substrate surface provided on the opposite side of the first substrate surface, and a plurality of first through holes, each of the first through holes through which each of multiple charged particle beams passes; a plurality of first electrodes, each of the first electrodes being provided on each of the first through holes, and each of the first electrodes including a first end and a second end; a plurality of second electrodes, each of the second electrodes being provided on each of the first through holes, being arranged to face each of the first electrodes, and including a third end facing the first end and a fourth end facing the second end; a plurality of third electrodes, each of the third electrodes being connected to the first end and extending toward the third end; a plurality of fourth electrodes, each of the fourth electrodes being connected to the second end and extending toward the fourth end; a plurality of fifth electrodes, each of the fifth electrodes being connected to the third end, each of the fifth electrodes being provided separately from each of the third electrodes, and each of the fifth electrodes extending toward the first end; and a plurality of sixth electrodes, each of the sixth electrodes being connected to the fourth end, each of the sixth electrodes being provided separately from each of the fourth electrodes, and each of the sixth electrodes extending toward the second end.

The plurality of first electrodes 10, the plurality of second electrodes 20, the plurality of third electrodes 30, the plurality of fourth electrodes 32, the plurality of fifth electrodes 34, and the plurality of sixth electrodes 36, are provided in the plurality of first through holes 80. As a result, the electrode shape controllability is improved. For example, the control of the inter-electrode distance (inter-electrode pitch) corresponds to the control of the distance between the groove 162a and the groove 162b in the manufacturing process. The distance between the groove 162a and the groove 162b can be easily controlled by using the lithography method. The height of the electrode corresponds to the depth of the groove 162 in the manufacturing process. The depth of such groove 162 can also be easily controlled using RIE method. Therefore, it is possible to provide an electronic component that increases the intensity of the deflection electric field and reduces the variation in the intensity of the deflection electric field.

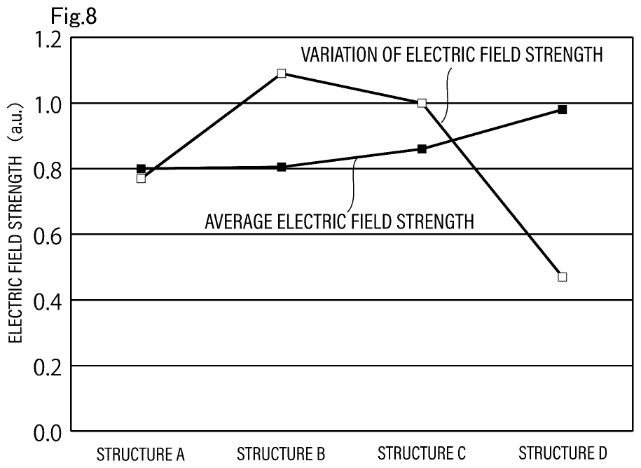

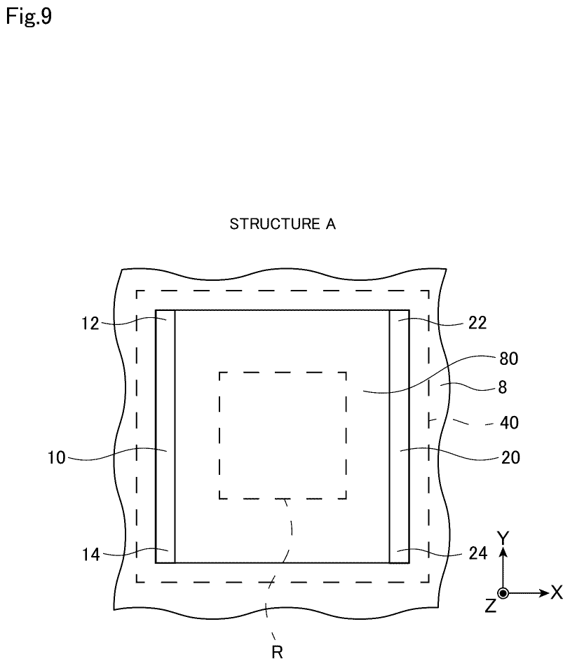

FIG. 8 is the graph showing the change in the average electric field strength and the change in the variation of the electric field strength due to the difference in the shapes of the electrodes. Note that the average electric field strength and the variation of the electric field strength were calculated using the electron beam passing area R shown after FIG. 9. The electron beam passing area R has a square shape having a length of ½ of the distance between the first electrode 10 and the second electrode 20 as one side. The electron beam passing area R is provided at the center of the first through hole 80 when viewed from above.

FIG. 9 is a schematic top view showing the electrode according to structure A described in FIG. 8, which is the comparative example of the first embodiment. For electrodes according to structure A, the third electrode 30, the fourth electrode 32, the fifth electrode 34 and the sixth electrode 36 are not provided.

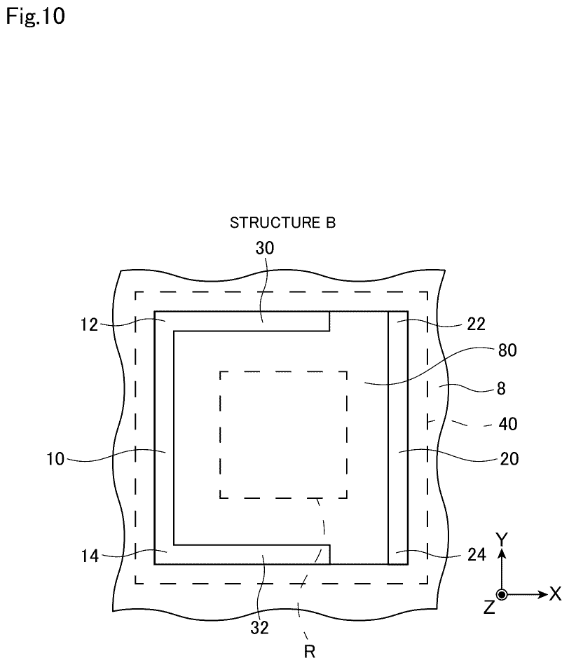

FIG. 10 is the schematic top view showing the electrode according to structure B described in FIG. 8, which is the comparative example of the first embodiment. For electrodes according to structure B, the fifth electrode 34 and the sixth electrode 36 are not provided. Further, in structure B, the third electrode 30 and the third end 22 are closer to each other. Further, in structure B, the fourth electrode 32 and the fourth end 24 are closer to each other.

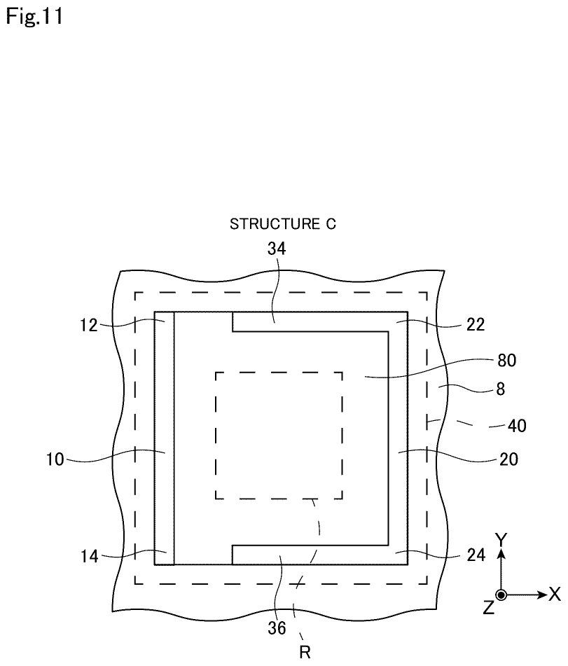

FIG. 11 is the schematic top view showing the electrode according to structure C described in FIG. 8, which is the comparative example of the first embodiment. For electrodes according to structure C, the third electrode 30 and the fourth electrode 32 are not provided. Further, for electrodes according to structure C, the fifth electrode 34 and the first end 12 are closer to each other. Further, for electrodes according to the structure C, the sixth electrode 36 and the second end 14 are closer to each other.

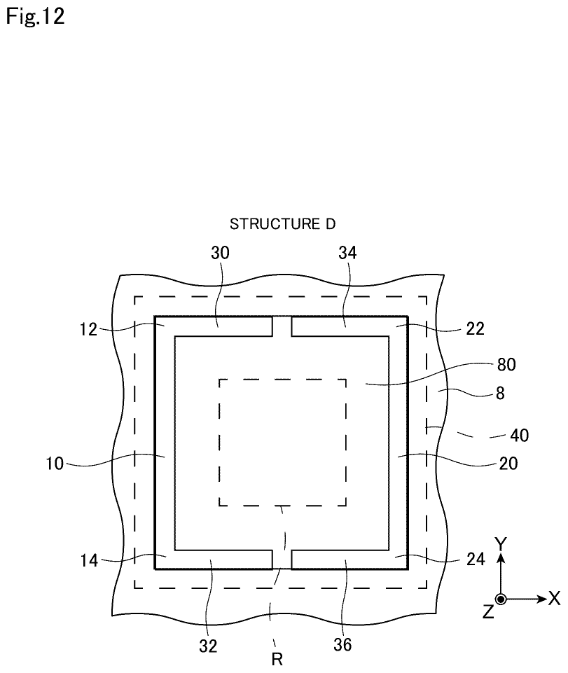

FIG. 12 is the schematic top view showing the electrode according to the structure D described in FIG. 8. For electrodes according to the structure D, the third electrode 30, the fourth electrode 32, the fifth electrode 34 and the sixth electrode 36 are provided. The electrode according to structure D is an electrode of the present embodiment.

As shown in FIG. 8, for electrodes according to the structure D, it has the highest average electric field strength and the smallest variation of the electric field strength. Therefore, it is preferable that the third electrode 30 connected to the first end 12 and extending toward the third end 22, the fourth electrode 32 connected to the second end 14 and extending toward the fourth end 24, the fifth electrode 34 connected to the third end 22, provided separately from the third electrode 30 and extending toward the first end 12, and the sixth electrode 36 connected to the fourth end 24, provided separately from the fourth electrode 32, and extending toward the second end 14, are provided.

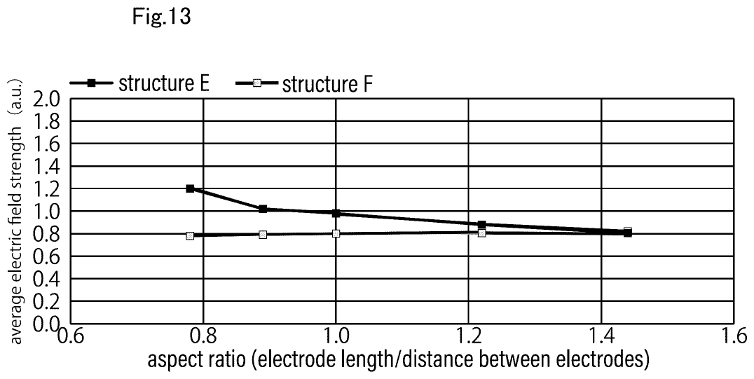

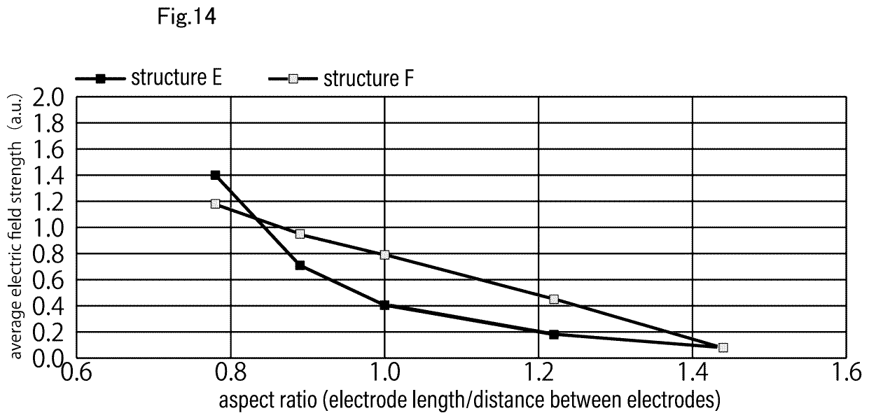

FIG. 13 is the graph showing the change in the average electric field strength due to the difference in the length of the first electrode 10 and the length of the second electrode 20. FIG. 14 is the graph showing the change in the variation of the electric field strength due to the difference in the length of the first electrode and the length of the second electrode.

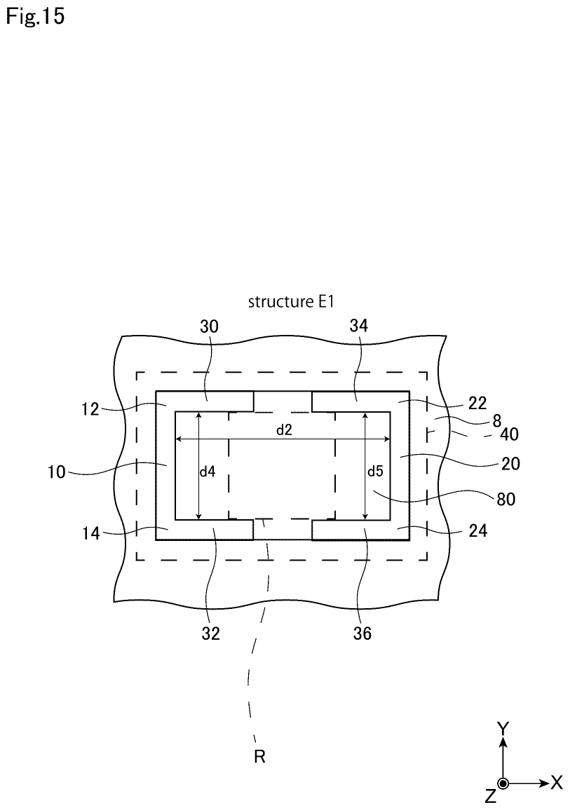

FIG. 15 is the schematic top view showing the example of the structure E shown in FIG. 13 and FIG. 14, which shows the electrode according to the structure E1, which is the example of the present embodiment. The distance d4 between the third electrode 30 and the fourth electrode 32 in the Y-direction and the distance d₅ between the fifth electrode 34 and the sixth electrode 36 in the Y-direction are 0.78 times the distance d₂ between the first electrode 10 and the second electrode 20 in the X-direction.

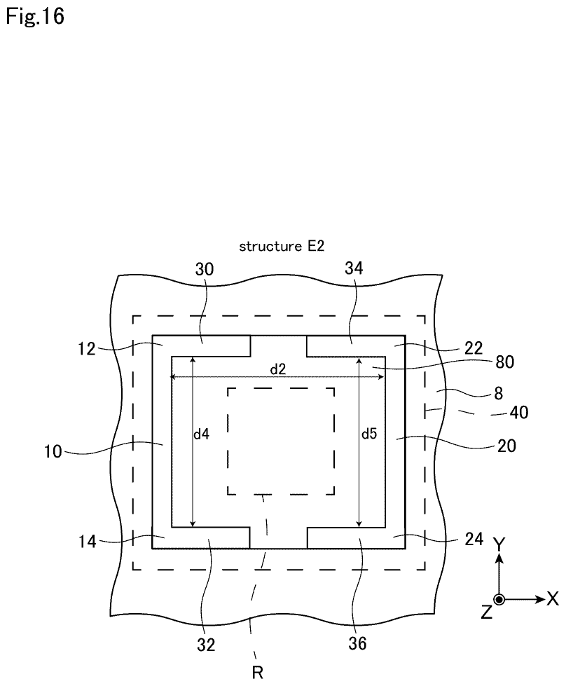

FIG. 16 is the schematic top view showing the example of the structure E shown in FIG. 13 and FIG. 14, which shows the electrode according to the structure E2, which is the example of the present embodiment. The distance d₄ between the third electrode 30 and the fourth electrode 32 in the Y-direction and the distance d₅ between the fifth electrode 34 and the sixth electrode 36 in the Y-direction are equal to the distance d₂ between the first electrode 10 and the second electrode 20 in the X-direction.

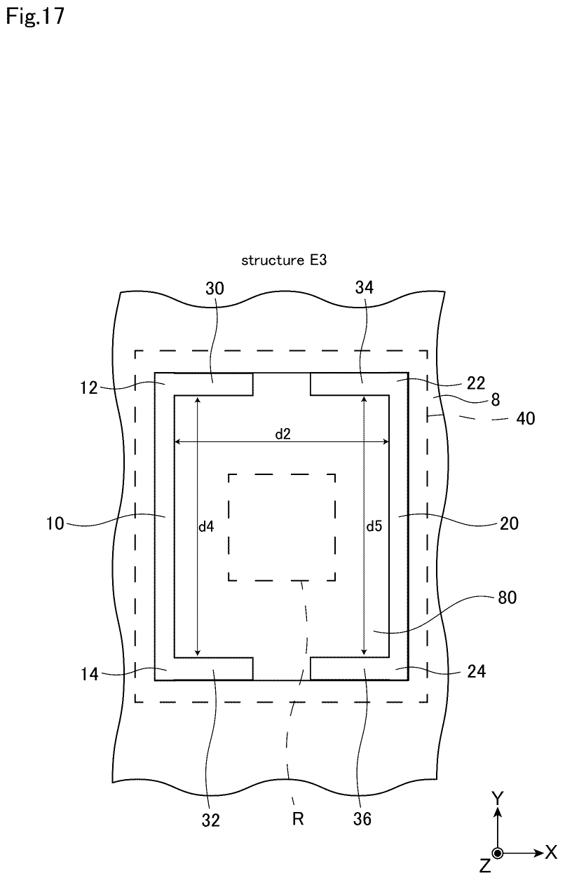

FIG. 17 is the schematic top view showing the example of the structure E shown in FIG. 13 and FIG. 14, which shows the electrode according to the structure E3, which is the example of the present embodiment. The distance d₄ between the third electrode 30 and the fourth electrode 32 in the Y-direction and the distance d₅ between the fifth electrode 34 and the sixth electrode 36 in the Y-direction are 1.41 times the distance d₂ between the first electrode 10 and the second electrode 20 in the X-direction.

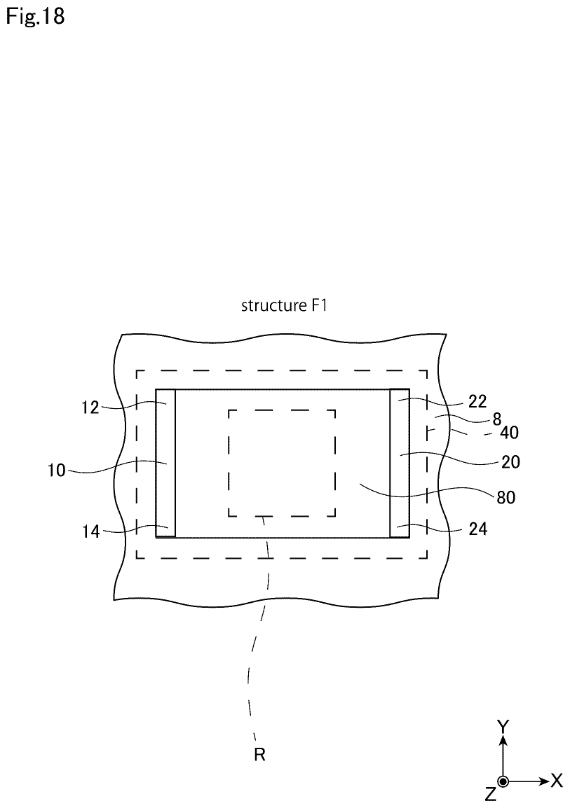

FIG. 18 is the schematic top view showing the example of the structure F shown in FIG. 13 and FIG. 14, which shows the example of the electrode according to structure F1, which is the comparative example of the present embodiment. This electrode is obtained by removing the third electrode 30, the fourth electrode 32, the fifth electrode 34, and the sixth electrode 36 from the electrode shown in FIG. 15.

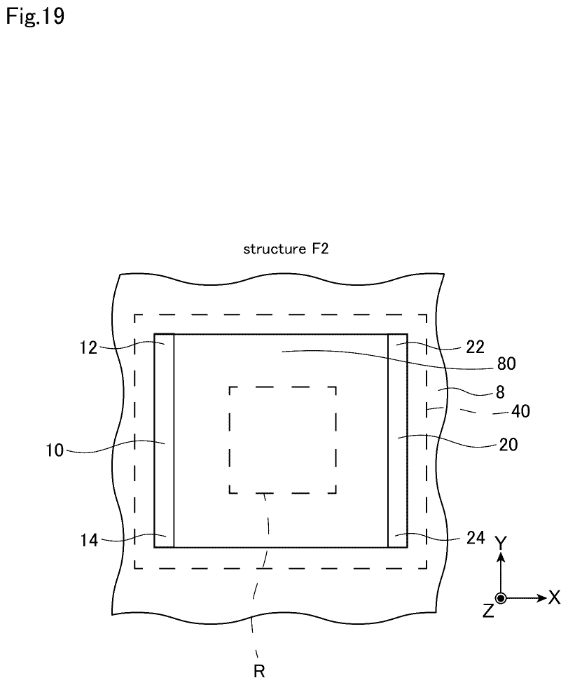

FIG. 19 is the schematic top view showing the example of the structure F shown in FIG. 13 and FIG. 14, which shows the electrode according to structure F2, which is the comparative example of the present embodiment. This electrode is obtained by removing the third electrode 30, the fourth electrode 32, the fifth electrode 34, and the sixth electrode 36 from the electrode shown in FIG. 16.

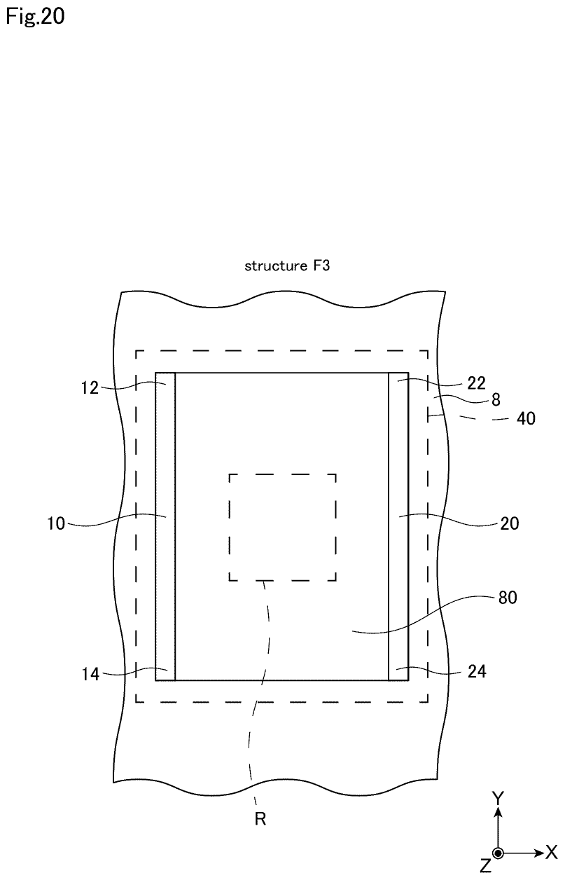

FIG. 20 is the schematic top view showing the example of the structure F shown in FIG. 13 and FIG. 14, which shows the electrode according to structure F3, which is the comparative example of the present embodiment. This electrode is obtained by removing the third electrode 30, the fourth electrode 32, the fifth electrode 34, and the sixth electrode 36 from the electrode shown in FIG. 17.

Except for the case where the distance between the third electrode 30 and the fourth electrode 32 in the Y-direction and the distance between the fifth electrode 34 and the sixth electrode 36 in the Y-direction are 0.78 times the distance between the first electrode 10 and the second electrode 20 in the X-direction, the electrode of the structure E including the third electrode 30, the fourth electrode 32, the fifth electrode 34 and the sixth electrode 36, is superior to the electrode of the structure F in both the average electric field strength (FIG. 13) and the variation of the electric field strength (FIG. 14).

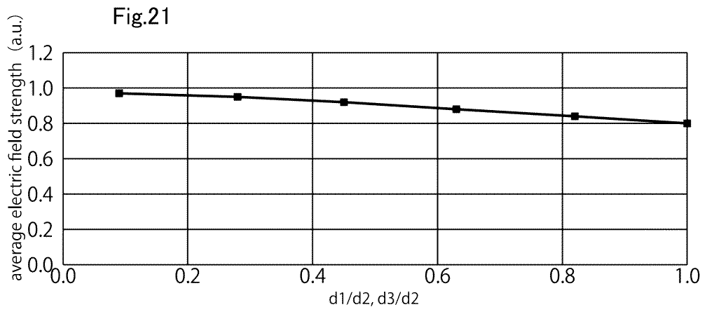

FIG. 21 is the graph showing the relationship between the ratio of the distance between the third electrode 30 and the fifth electrode 54 d₁ to the distance between the first electrode 10 and the second electrode 20 d₂ (d₁/d₂) and the ratio of the distance between the fourth electrode 32 and the sixth electrode 36 d₃ to the distance between the first electrode 10 and the second electrode 20 d₂ (d₃/d₂), and the average electric field strength.

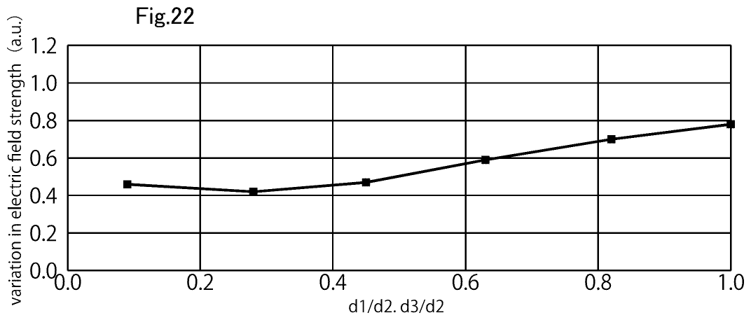

FIG. 22 is the graph showing the relationship between the ratio of the distance between the third electrode 30 and the fifth electrode 34 d₁ to the distance between the first electrode 10 and the second electrode 20 d₂ (d₁/d₂) and the ratio of the distance between the fourth electrode 32 and the sixth electrode 36 d₃ to the distance between the first electrode 10 and the second electrode 20 d₂ ((d₃/d₂)), and the variation of the electric field strength.

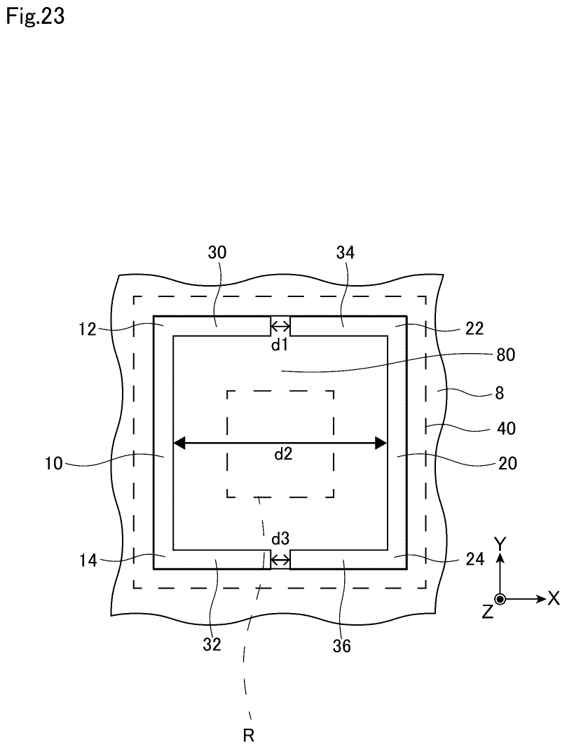

FIG. 23 is the schematic top view of the electrode of the present embodiment whose ratio of the distance between the third electrode 30 and the fifth electrode 54 d₁ to the distance between the first electrode 10 and the second electrode 20 d₂ (d₁/d₂) and whose ratio of the distance between the fourth electrode 32 and the sixth electrode 36 d₃ to the distance between the first electrode 10 and the second electrode 20 d₂ (d₃/d₂) are 0.09.

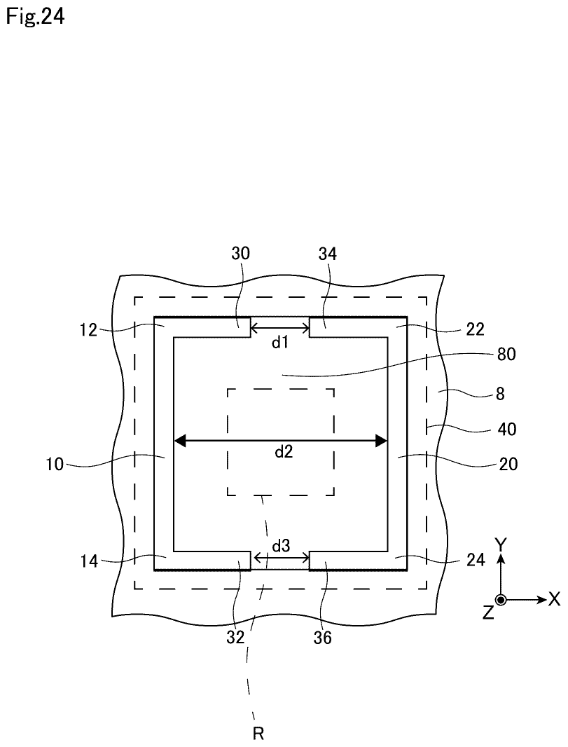

FIG. 24 is the schematic top view of the electrode of the present embodiment whose ratio of the distance between the third electrode 30 and the fifth electrode 34 d₁ to the distance between the first electrode 10 and the second electrode 20 d₂ (d₁/d₂) and whose ratio of the distance between the fourth electrode 32 and the sixth electrode 36 d₃ to the distance between the first electrode 10 and the second electrode 20 d₂ (d₃/d₂) are 0.27.

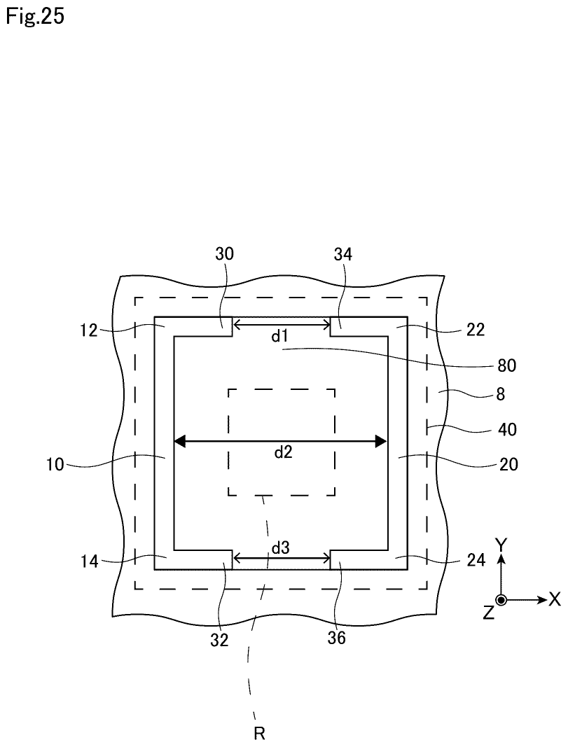

FIG. 25 is the schematic top view of the electrode of the present embodiment whose ratio of the distance between the third electrode 30 and the fifth electrode 34 d₁ to the distance between the first electrode 10 and the second electrode 20 d₂ (d₁/d₂) and whose ratio of the distance between the fourth electrode 32 and the sixth electrode 36 d₃ to the distance between the first electrode 10 and the second electrode 20 d₂ (d₃/d₂) are 0.45.

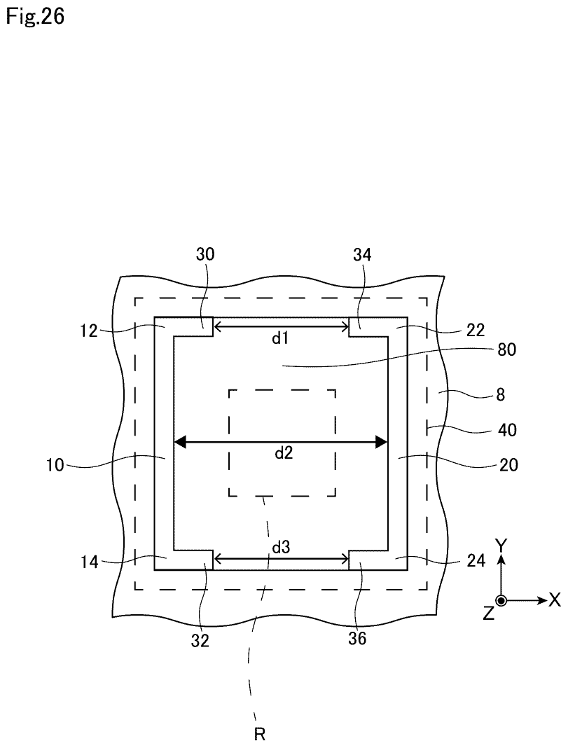

FIG. 26 is the schematic top view of the electrode of the present embodiment whose ratio of the distance between the third electrode 30 and the fifth electrode 34 d₁ to the distance between the first electrode 10 and the second electrode 20 d₂ (d₁/d₂) and whose ratio of the distance between the fourth electrode 32 and the sixth electrode 36 d₃ to the distance between the first electrode 10 and the second electrode 20 d₂ (d₃/d₂) are 0.63.

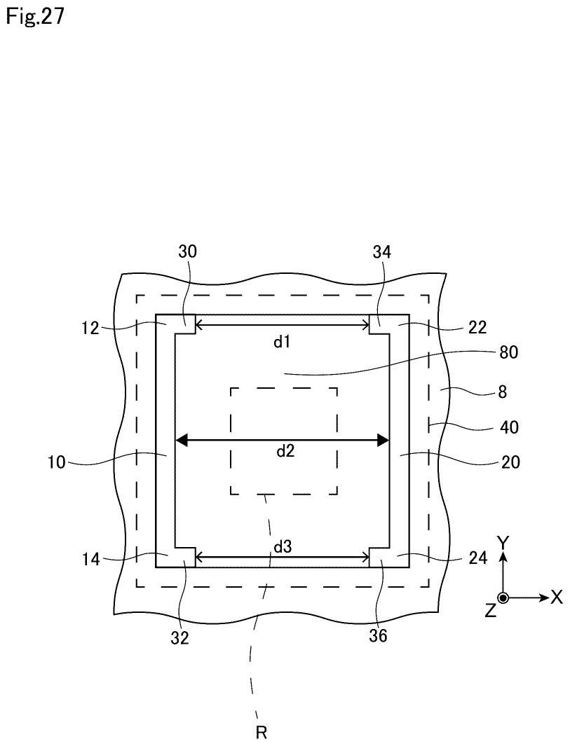

FIG. 27 is the schematic top view of the electrode of the present embodiment whose ratio of the distance between the third electrode 30 and the fifth electrode 34 d₁ to the distance between the first electrode 10 and the second electrode 20 d₂ (d₁/d₂) and whose ratio of the distance between the fourth electrode 32 and the sixth electrode 36 d₃ to the distance between the first electrode 10 and the second electrode 20 d₂ (d₃/d₂) are 0.82.

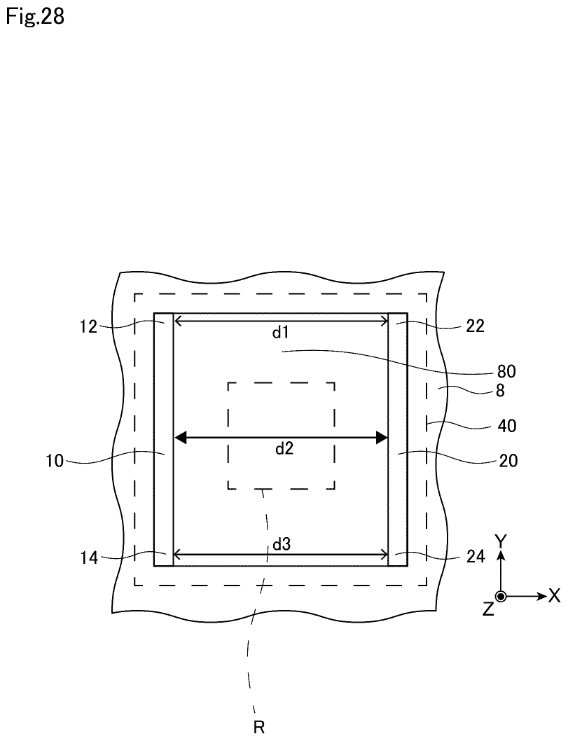

FIG. 28 is the schematic top view of electrodes without the third electrode 30, the fourth electrode 32, the fifth electrode 34 and the sixth electrode 36, which is a comparative example of the present embodiment. In other words, FIG. 28 is the schematic top view of the electrode whose ratio of the distance between the third electrode 30 and the fifth electrode 34 d₁ to the distance between the first electrode 10 and the second electrode 20 d₂ (d₁/d₂) and whose ratio of the distance between the fourth electrode 32 and the sixth electrode 36 d₃ to the distance between the first electrode 10 and the second electrode 20 d₂ (d₃/d₂) are 1.0.

In FIG. 21 to FIG. 28, it is assumed that d₁/d₂ and d₃/d₂ are equal.

When d₁/d₂ and d₃/d₂ are, for example, 0.1 or more and 0.4 or less, the variation of the electric field strength becomes sufficiently small. Incidentally, the variation of the electric field strength is the smallest when d₁/d₂ and d₃/d₂ is 0.3. When d₁/d₂ and d₃/d₂ are 0.1 or more and 0.4 or less, relatively high average electric field strength is ensured. Therefore, while reducing the variation of the electric field strength, in order to ensure a higher electric field strength, d₁/d₂ and d₃/d₂ is preferably 0.1 or more 0.4 or less. In other words, the distance d₁ between the third electrode 30 and the fifth electrode 34 is preferably 10% or more and 40% or less of the distance d₂ between the first electrode 10 and the second electrode 20, and more preferably, 30% or less. The distance d₃ between the fourth electrode 32 and the sixth electrode 36 is preferably 10% or more and 40% or less of the distance d₂ between the first electrode 10 and the second electrode 20, and more preferably, 30% or less.

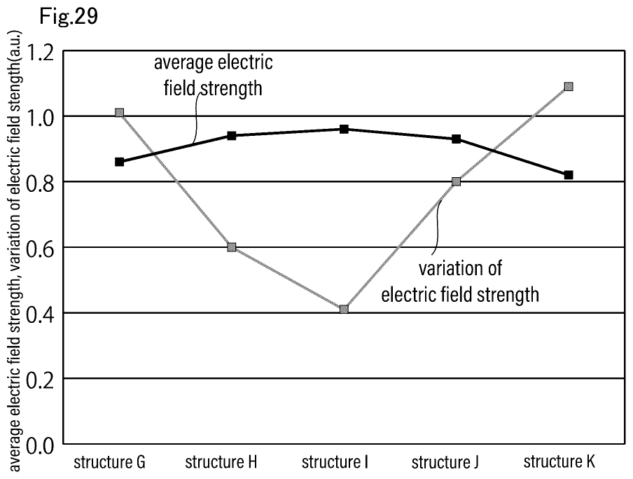

FIG. 29 is the graph showing the relationship between the difference of the position of the end of the third electrode 30, the difference of the position of the end of the fourth electrode 32, the difference of the position of the end of the fifth electrode 34, and the difference of the position of the end of the sixth electrode 36, and the average electric field strength and the variation of the electric field strength.

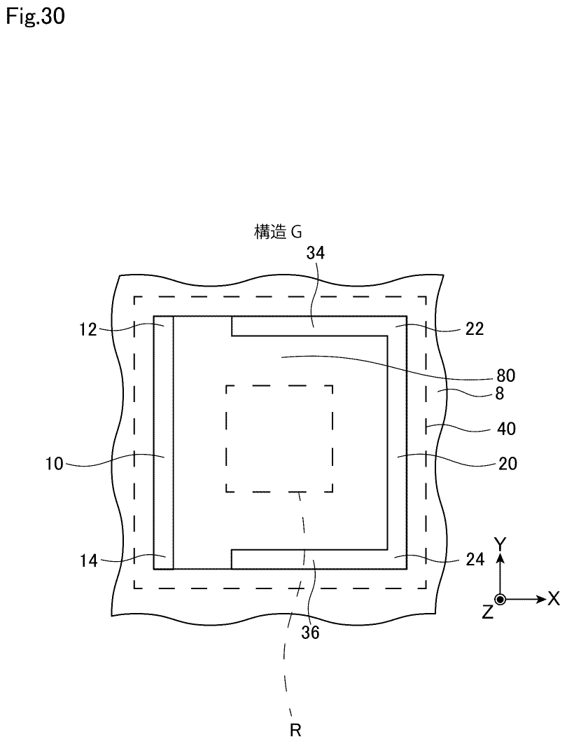

FIG. 30 is the schematic top view of the structure G of FIG. 29, which is the comparative embodiment of the present embodiment. The electrode according to the structure G does not include the third electrode 30 and the fourth electrode 32. For electrodes according to the structure G, the fifth electrode 34 is closest to the first end 12. For electrodes according to the structure G, the sixth electrode 36 is closest to the second end 14.

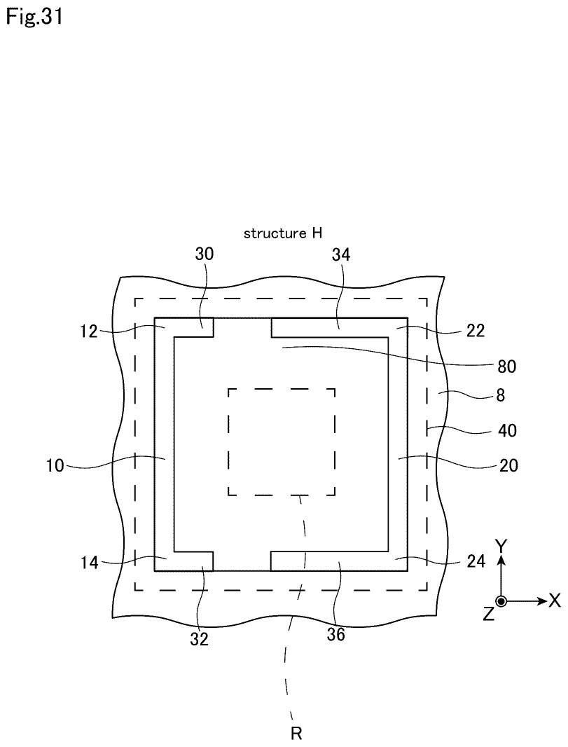

FIG. 31 is the schematic top view of the electrode of the structure H of FIG. 29, which is the electrode of the present embodiment. For electrodes according to the structure H, the length of the fifth electrode 34 is shorter than the length of the fifth electrode 34 of the structure G. For electrodes according to the structure H, the length of the sixth electrode 36 is shorter than the length of the sixth electrode 36 of the structure G. For electrodes according to the structure H, unlike the electrode according to the structure G, a short third electrode 30 and a short fourth electrode 32 are provided.

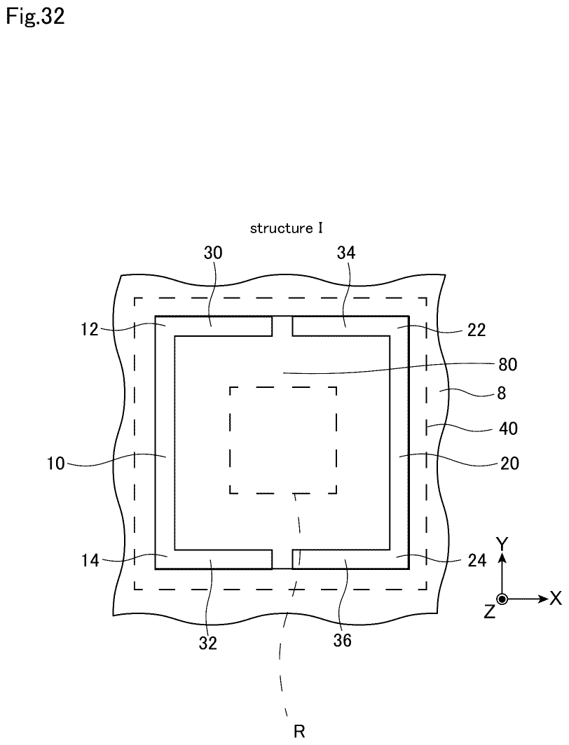

FIG. 32 is the schematic top view of the electrode of the structure I of FIG. 29, which is the electrode of the present embodiment. For electrodes according to the structure I, the length of the fifth electrode 34 is shorter than the length of the fifth electrode 34 of the structure H. For electrodes according to the structure I, the length of the sixth electrode 36 is shorter than the length of the sixth electrode 36 of the structure H. For electrodes according to the structure I, the length of the third electrode 30 is longer than the length of the third electrode 30 of the structure H. For electrodes according to the structure I, the length of the fourth electrode 32 is longer than the length of the fourth electrode 32 of the structure H. For electrodes according to the structure I, the lengths of the third electrode 30, the fourth electrode 32, the fifth electrode 34 and the sixth electrode 36 are all equal.

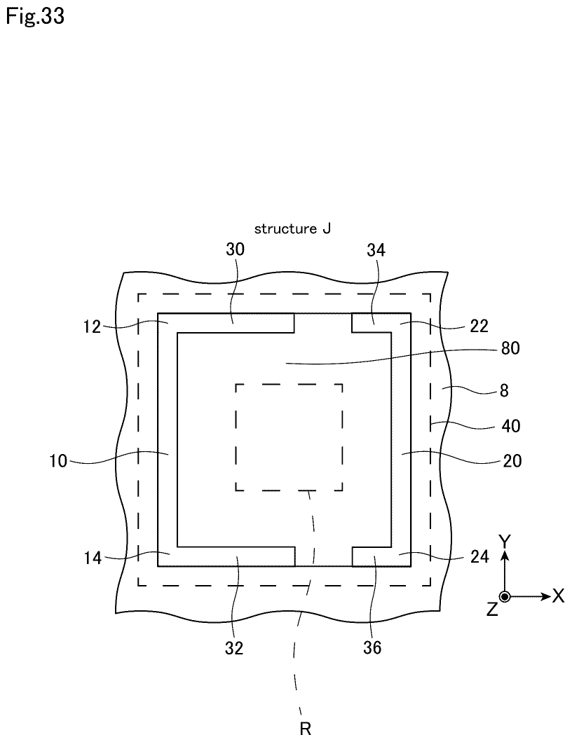

FIG. 33 is the schematic top view of the electrode of the structure J of FIG. 29, which is the electrode of the present embodiment. For electrodes according to the structure J, the length of the fifth electrode 34 is shorter than the length of the fifth electrode 34 of the structure I. For electrodes according to the structure J, the length of the sixth electrode 36 is shorter than the length of the sixth electrode 36 of the structure I. For electrodes according to the structure J, the length of the third electrode 30 is longer than the length of the third electrode 30 of the structure I. For electrodes according to the structure J, the length of the fourth electrode 32 is longer than the length of the fourth electrode 32 of the structure I.

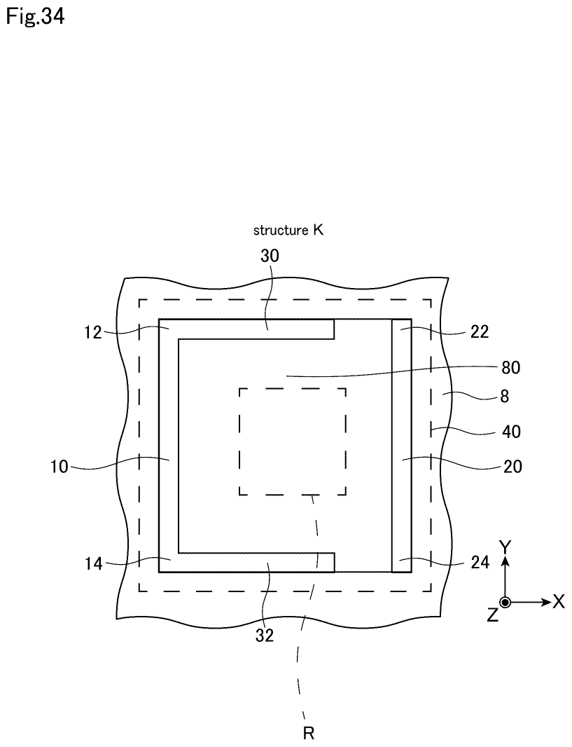

FIG. 34 is the schematic top view of the electrode of the structure K of FIG. 29, which is the comparative example of the present embodiment. The electrode according to the structure K does not have the fifth electrode 34 and the sixth electrode 36. For electrodes according to the structure K, the third electrode 30 is closest to the third end 22. For electrodes according to the structure K, the fourth electrode 32 is closest to the fourth end 24.

The electrode according to the structure I of FIG. 32 has the largest average electric field strength and the smallest variation of the electric field strength. Therefore, the length of the third electrode 30 and the length of the fifth electrode 34 are preferably equal. Further, the length of the fourth electrode 32 and the length of the sixth electrode 36 are preferably equal.

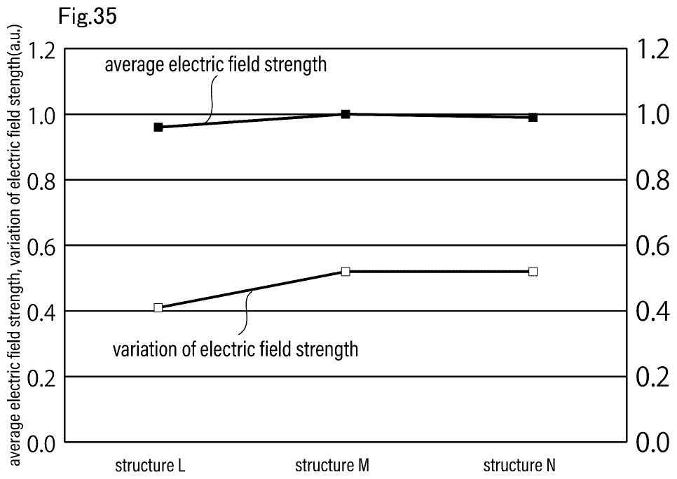

FIG. 35 is the graph showing the relationship between the length of the electrode in the Y-direction, and the average electric field strength and the variation of the electric field strength.

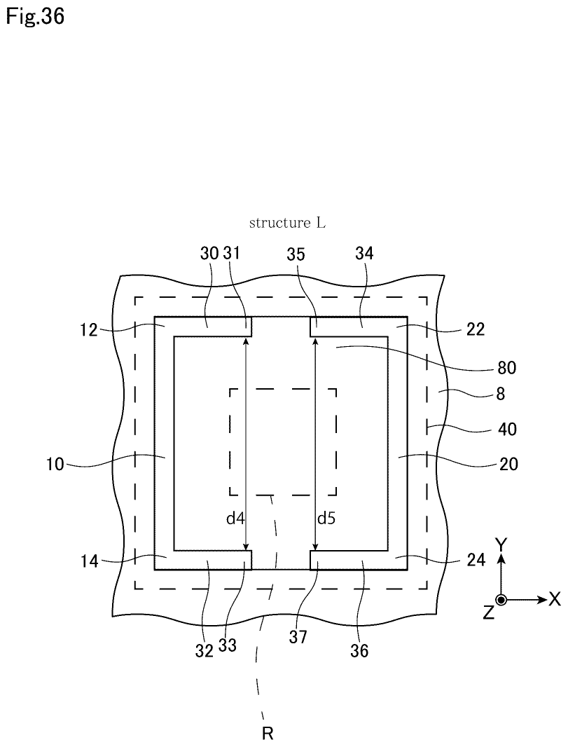

FIG. 36 is the schematic top view of the electrode of the structure L of FIG. 35, which is the electrode of the present embodiment. For electrodes according to the structure L, the length of the first electrode 10 in the Y-direction is equal to the length of the second electrode 20 in the Y-direction.

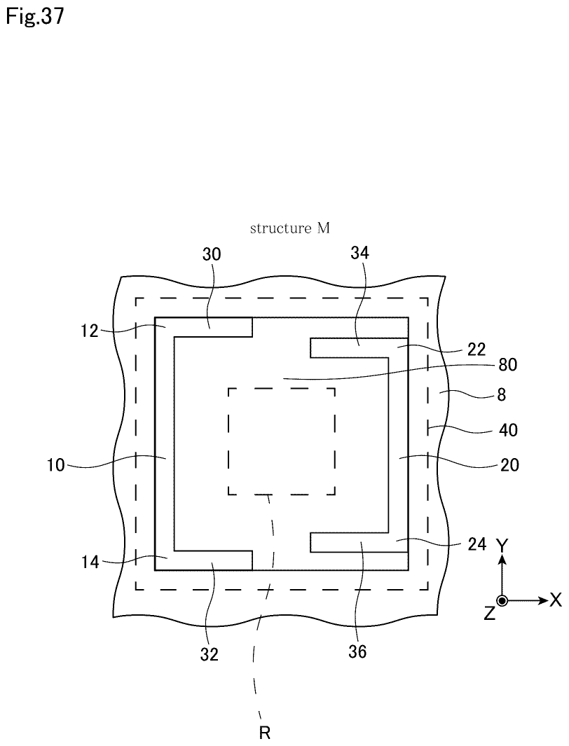

FIG. 37 is the schematic top view of the electrode of the structure M of FIG. 35, which is the electrode of the present embodiment. For electrodes according to the structure M, the length of the first electrode 10 in the Y-direction is longer than the second electrode 20 in the Y-direction.

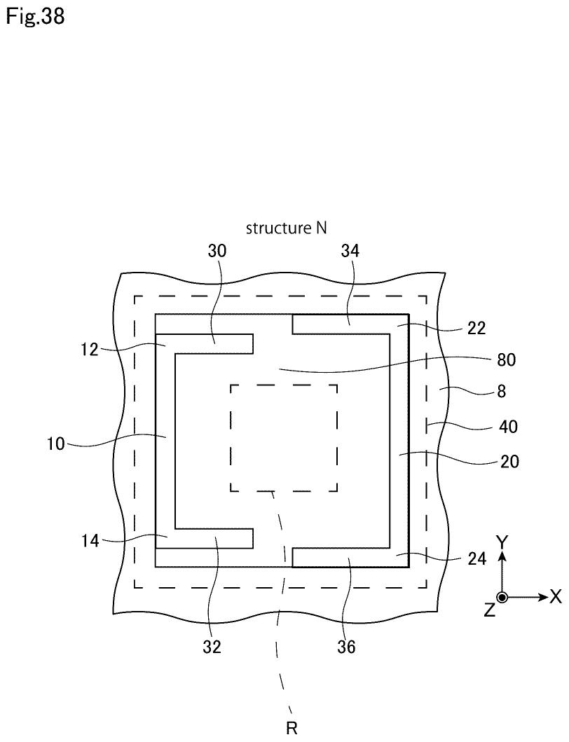

FIG. 38 is the schematic top view of the electrode according to the structure N of FIG. 35, which is the electrode of the present embodiment. For electrodes according to the structure N, the length of the first electrode 10 in the Y-direction is shorter than the length of the second electrode 20 in the Y-direction.

For electrodes according to the structure L of FIG. 36, the variation in electric field strength is the smallest. Therefore, the length of the first electrode 10 is preferably equal to the length of the second electrode 20.

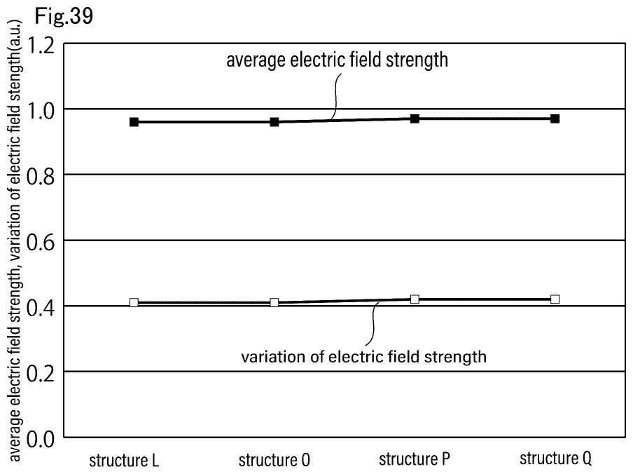

FIG. 39 is the graph showing the average electric field strength and the variation of the electric field strength depending on the difference of the structure of the first electrode 10 and the third electrode 30 in the vicinity of the first end 12, the structure of the first electrode 10 and the fourth electrode 42 in the vicinity of the second end 14, the structure of the second electrode 20 and the fifth electrode 34 in the vicinity of the third end 22, and the structure of the second electrode 20 and the sixth electrode 36 in the vicinity of the fourth end 24.

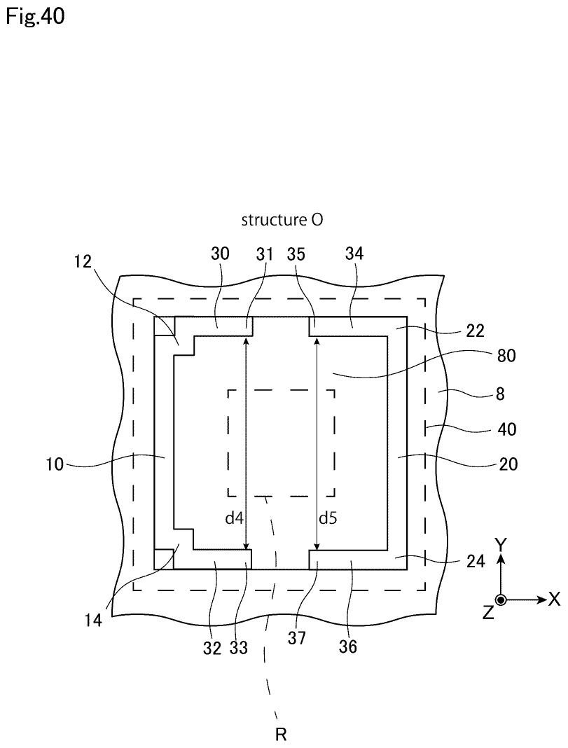

FIG. 40 is the schematic top view of the electrode of the structure O of FIG. 39, which is the electrode of the present embodiment. For electrodes according to the structure O, the structure in the vicinity of the third end 22 and the structure in the vicinity of the fourth end 24 are the same as that of the structure L shown in FIG. 36. On the other hand, for electrodes according to the structure O, the structure in the vicinity of the first end 12 and the structure in the vicinity of the second end 14 are different from that of the electrode according to the structure L of FIG. 36. The electrode in the vicinity of the first end 12 and the electrode in the vicinity of the second end 14 in the structure O are closer to the electron beam passing area R than the electrode in the vicinity of the first end 12 and the electrode in the vicinity of the second end 14 in the structure L.

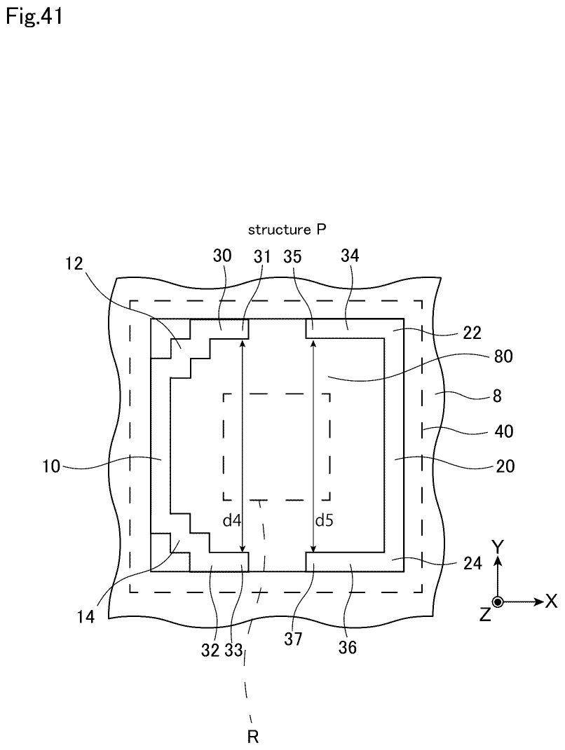

FIG. 41 is the schematic top view of the electrode of the structure P of FIG. 39, which is the electrode of the present embodiment. For electrodes according to the structure P, the structure in the vicinity of the third end 22 and the structure in the vicinity of the fourth end 24 are the same as that of the structure L shown in FIG. 36. On the other hand, for electrodes according to the structure P, the structure in the vicinity of the first end 12 and the structure in the vicinity of the second end 14 are different from those of the structure L of FIG. 36. The electrode in the vicinity of the first end 12 and the electrode in the vicinity of the second end 14 in the structure P are closer to the electron beam passing area R than the electrode in the vicinity of the first end 12 and the electrode in the vicinity of the second end 14 in the structure O.

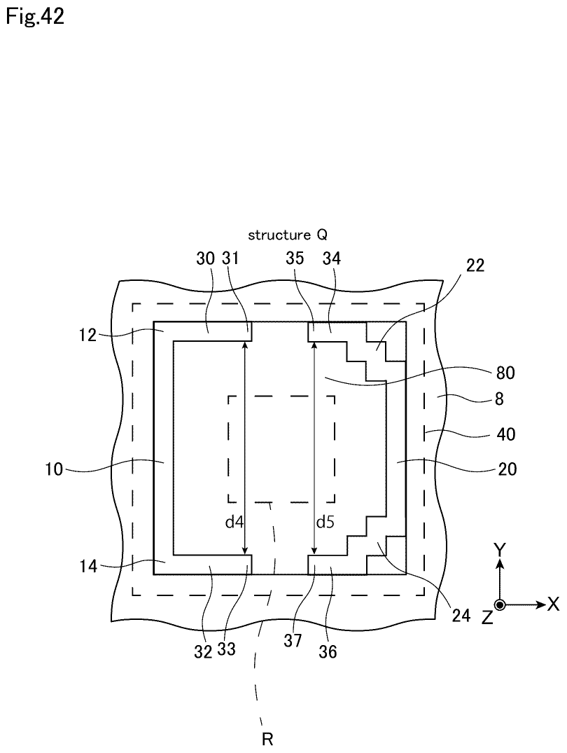

FIG. 42 is the schematic top view of the electrode of the structure Q of FIG. 39, which is the electrode of the present embodiment. For electrodes according to the structure Q, the structure in the vicinity of the first end 12 and the structure in the vicinity of the second end 14 are the same as that of the structure L shown in FIG. 36. On the other hand, for electrodes according to the structure Q, the structure in the vicinity of the third end 22 and the structure in the vicinity of the fourth end 24 are different from those of the structure L of FIG. 36. The electrode in the vicinity of the third end 22 and the electrode in the vicinity of the fourth end 24 in the structure Q are closer to the electron beam passing area R than the electrode in the vicinity of the third end 22 and the electrode in the vicinity of the fourth end 24 in the structure L. The electrodes in the vicinity of the third end 22 and in the vicinity of the fourth end 24 in the structure Q are the same as those obtained by folding the electrodes in the vicinity of the first end 12 and the second end 14 in the structure P at the YZ-plane.

As shown in FIG. 39, there is no significant difference between the average electric field strength and the variation of the electric field strength in any of the structure L, the structure O, the structure P, and the structure Q.

It is difficult to manufacture the structure of the electrodes in the vicinity of the first end 12, in the vicinity of the second end 14, in the vicinity of the third end 22, and in the vicinity of the fourth end 24 into a rectangular structure as shown in FIG. 2. The structure of the electrodes in the vicinity of the first end 12, in the vicinity of the second end 14, in the vicinity of the third end 22, and in the vicinity of the fourth end 24 may have an octagonal shape or a chamfered (R-chamfered) shape as shown in, for example, FIG. 3. The graph in FIG. 39 shows that the average electric field strength and the variation of electric field strength do not change much even if the electrode structures in the vicinity of the first end 12, in the vicinity of the second end 14, in the vicinity of the third end 22, and in the vicinity of the fourth end 24 have octagonal shapes or square shapes with chamfered corners.

In any of the structures L, O, P, and Q, it is preferable that the distance d₄ between the fifth end 31 of the third electrode 30 facing the fifth electrode 34 and the sixth end 33 of the fourth electrode 32 facing the sixth electrode 36 is equal to the distance d₅ between the seventh end 35 of the fifth electrode 34 facing the third electrode 30 and the eighth end 37 of the sixth electrode 36 facing the fourth electrode 32. Therefore, the distance d₄ is preferably equal to the distance d₅.

According to the electronic component and the charged particle beam irradiation apparatus of the present embodiment, it is possible to provide the electronic component and the charged particle beam irradiation apparatus that increase the variation of the strength of the deflection electric field and reduce the variation of the strength of the deflection electric field.

### Second Embodiment

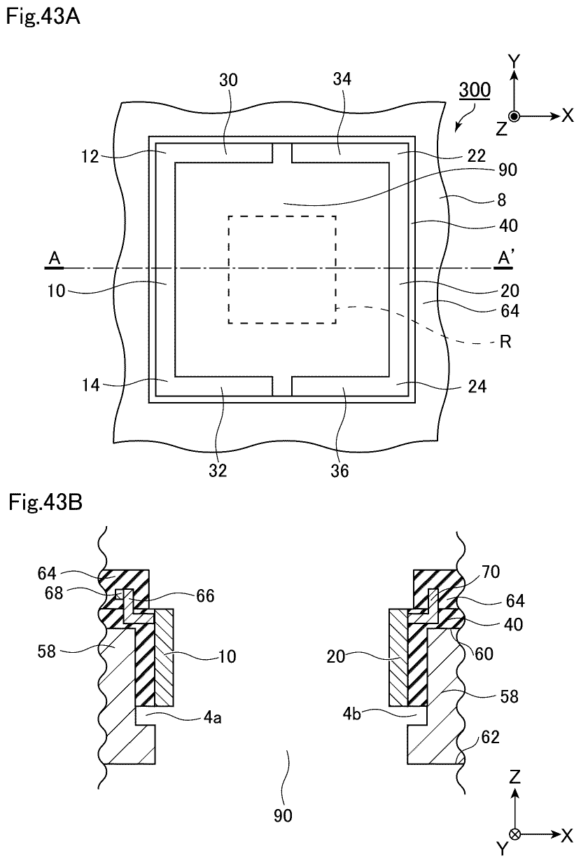

FIGS. 43A-B are schematic top views of a main part of the electronic component 300 of the present embodiment. Descriptions of the contents overlapping with those of the first embodiment will be omitted.

In the electronic component 300, the insulating film 40, the first electrode 10, and the second electrode 20 are formed in the second through hole 90 of the circuit board 58 instead of the first through hole 80 of the first substrate 2. Similarly, in the electronic component 300, the third electrode 30, the fourth electrode 32, the fifth electrode 34, and the sixth electrode 36 are formed in the second through hole 90.

In the present embodiment, the second through hole 90 corresponds to the opening 108 (FIG. 1).

In the present embodiment, the second through hole 90 is an example of the first through hole 80.

According to the electronic component and the charged particle beam irradiation apparatus of the present embodiment, it is possible to provide the electronic component and the charged particle beam irradiation apparatus that increase the variation of the strength of the deflection electric field and reduce the variation of the strength of the deflection electric field.

### Third Embodiment

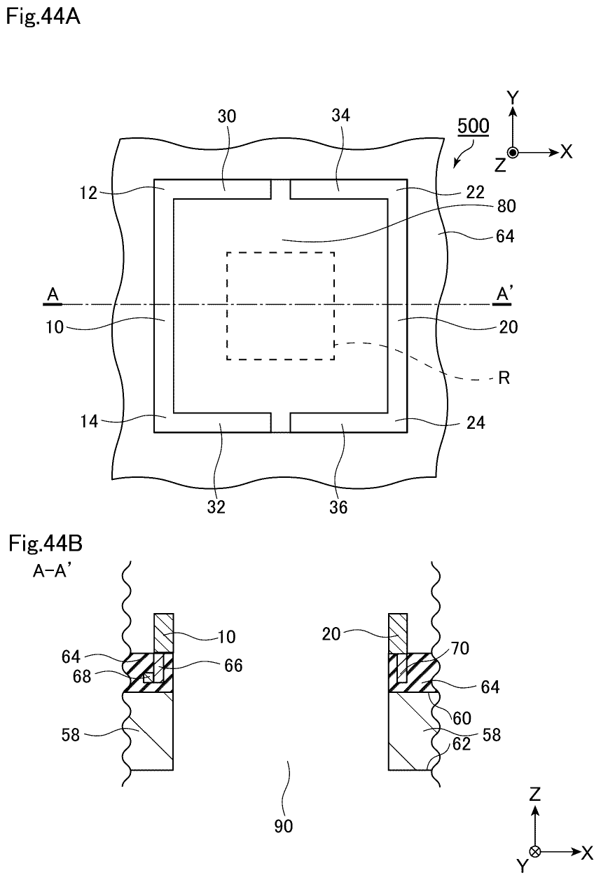

FIGS. 44A-B are schematic top views of a main part of the electronic component 500 of the present embodiment. Descriptions of contents overlapping with those of the first embodiment and the second embodiment will be omitted.

In the electronic component 500, the first electrode 10, the second electrode 20, the third electrode 30, the fourth electrode 32, the fifth electrode 34, and the sixth electrode 36 are provided on the second insulating film 64. The first electrode 10, the second electrode 20, the third electrode 30, the fourth electrode 32, the fifth electrode 34, and the sixth electrode 36 include, for example, gold.

In the present embodiment, the second through hole 90 corresponds to the opening 108 (FIG. 1).

According to the electronic component and the charged particle beam irradiation apparatus of the present embodiment, it is possible to provide the electronic component and the charged particle beam irradiation apparatus that increase the variation of the strength of the deflection electric field and reduce the variation of the strength of the deflection electric field.

The charged particle beam irradiation apparatus including the multi charged particle beam irradiation apparatus includes the charged particle beam writing apparatus writing a mask pattern on a mask blank using the charged particle beam including the electron beam, and the charged particle beam inspection apparatus for inspecting the mask pattern by detecting secondary electrons generated by irradiating the mask pattern with the electron beam.

The electronic components described in the above embodiments are applicable to the charged particle beam irradiation apparatus including the multi charged particle beam irradiation apparatus. In other words, the electronic component described in the above embodiment is applicable to the charged particle beam inspection apparatus including the multi charged particle beam inspection apparatus in addition to the charged particle beam writing apparatus including the multi charged particle beam writing apparatus.

While certain embodiments and examples have been described, these embodiments and examples have been presented by way of example only, and are not intended to limit the scope of the inventions. These novel embodiments can be implemented in various other forms, and various omissions, replacements, and modifications can be made without departing from the gist of the invention. These embodiments and variations thereof fall within the scope and spirit of the invention, and fall within the scope of the invention described in the claims and equivalents thereof.

The above described embodiments can be summarized in the following technical solutions.
(Technical Proposal 1) An electronic component including:
   a first substrate including a first substrate surface, a second substrate surface provided on the opposite side of the first substrate surface, and a plurality of first through holes, each of the first through holes through which each of multiple charged particle beams passes;
   a plurality of first electrodes, each of the first electrodes being provided on each of the first through holes, and each of the first electrodes including a first end and a second end;
   a plurality of second electrodes, each of the second electrodes being provided on each of the first through holes, being arranged to face each of the first electrodes, and including a third end facing the first end and a fourth end facing the second end;
   a plurality of third electrodes, each of the third electrodes being connected to the first end and extending toward the third end;
   a plurality of fourth electrodes, each of the fourth electrodes being connected to the second end and extending toward the fourth end;
   a plurality of fifth electrodes, each of the fifth electrodes being connected to the third end, each of the fifth electrodes being provided separately from each of the third electrodes, and each of the fifth electrodes extending toward the first end; and
   a plurality of sixth electrodes, each of the sixth electrodes being connected to the fourth end, each of the sixth electrodes being provided separately from each of the fourth electrodes, and each of the sixth electrodes extending toward the second end.
(Technical Proposal 2) The electronic component according to technical proposal 1,
   wherein a distance between the third electrode and the fifth electrode is 10% or more and 40% or less of a distance between the first electrode and the second electrode, and
   a distance between the fourth electrode and the sixth electrode is 10% or more and 40% or less of the distance between the first electrode and the second electrode,
(Technical Proposal 3) The electronic component according to technical proposal 1 or 2,
   wherein a distance between a fifth end of the third electrode facing the fifth electrode and a sixth end of the fourth electrode facing the sixth electrode is equal to a distance between a seventh end of the fifth electrode facing the third electrode and an eighth end of the sixth electrode facing the fourth electrode.
(Technical Proposal 4) The electronic component according to any one of technical proposals 1 to 3,
   wherein a length of the first electrode and a length of the second electrode are equal.
(Technical Proposal 5) The electronic component according to any one of technical proposals 1 to 4,
   wherein a length of the third electrode and the length of the fifth electrode are equal, and
   a length of the fourth electrode and a length of the sixth electrode are equal.
(Technical Proposal 6) The electronic component according to any one of technical proposals 1 to 5,
   wherein each of the first electrodes, each of the second electrodes, each of the third electrodes, each of the fourth electrodes, each of the fifth electrodes and each of the sixth electrodes are provided in each of the first through holes.
(Technical Proposal 7) The electronic component according to any one of technical proposals 1 to 6,
   wherein the first substrate includes Si (silicon), and
   the first electrodes, the second electrodes, the third electrodes, the fourth electrodes, the fifth electrodes, and the sixth electrodes include metal nitride or W (tungsten).
(Technical Proposal 8) The electronic component according to technical proposal 6, further including:
   an insulating film provided between the first substrate and the first electrodes, the second electrodes, the third electrodes, the fourth electrodes, the fifth electrodes and the sixth electrodes.
(Technical Proposal 9) The electronic component according to technical proposal 8,
   wherein the insulating film includes silicon oxide.
(Technical Proposal 10) The electronic component according to technical proposal 8,
   wherein the first substrate is a semiconductor substrate, and
   each of the side surfaces of the first through holes include an exposed portion in the vicinity of the second substrate surface.
(Technical Proposal 11) The electronic component according to technical proposal 10,
   wherein the first substrate further includes a plurality of concavities on each of the side surfaces between the insulating film and the second substrate surface, and each of the concavities surrounding each of the first through holes.
(Technical Proposal 12) The electronic component according to technical proposal 6, further including:
   a plurality of first junction electrodes provided on the first substrate surface, and each of the first junction electrodes being electrically connected to each of the first electrodes;
   a plurality of second junction electrodes provided on the first substrate surface, and each of the second junction electrodes being electrically connected to each of the second electrodes;
   a second substrate including a plurality of second through holes and a third substrate surface facing the first substrate surface;
   a plurality of third junction electrodes provided on the third substrate surface, each of the third junction electrodes being electrically connected to each of the first junction electrodes; and
   a plurality of fourth junction electrodes provided on the third substrate surface, each of the fourth junction electrodes being electrically connected to each of the second junction electrodes.
(Technical Proposal 13) The electronic component according to technical proposal 12,
   wherein the first junction electrodes, the second junction electrodes, the third junction electrodes, and the fourth junction electrodes include Au (gold) or Cu (copper).
(Technical Proposal 14) A charged particle beam irradiation apparatus including the electronic component according to any one of technical proposals 1 to 13.

While certain embodiments have been described, these embodiments have been presented by way of example only, and are not intended to limit the scope of the inventions. The electronic component and charged particle beam irradiation apparatus described herein may be embodied in a variety of other forms; furthermore, various omissions, substitutions and changes in the form of the devices and methods described herein may be made without departing from the spirit of the inventions. with Indeed, electronic components The accompanying claims and their equivalents are intended to cover such forms or modifications as would fall within the scope and spirit of the inventions.

What is claimed is:

1. An electronic component comprising:
a first substrate including a first substrate surface, a second substrate surface provided on the opposite side of the first substrate surface, and a plurality of first through holes, each of the first through holes through which each of multiple charged particle beams passes;
a plurality of first electrodes, each of the first electrodes being provided on each of the first through holes, and each of the first electrodes including a first end and a second end;
a plurality of second electrodes, each of the second electrodes being provided on each of the first through holes, being arranged to face each of the first electrodes, and including a third end facing the first end and a fourth end facing the second end;
a plurality of third electrodes, each of the third electrodes being connected to the first end and extending toward the third end;
a plurality of fourth electrodes, each of the fourth electrodes being connected to the second end and extending toward the fourth end;
a plurality of fifth electrodes, each of the fifth electrodes being connected to the third end, each of the fifth electrodes being provided separately from each of the third electrodes, and each of the fifth electrodes extending toward the first end; and
a plurality of sixth electrodes, each of the sixth electrodes being connected to the fourth end, each of the sixth electrodes being provided separately from each of the fourth electrodes, and each of the sixth electrodes extending toward the second end.

2. The electronic component according to claim 1,
wherein a distance between the third electrode and the fifth electrode is 10% or more and 40% or less of a distance between the first electrode and the second electrode, and
a distance between the fourth electrode and the sixth electrode is 10% or more and 40% or less of the distance between the first electrode and the second electrode,

3. The electronic component according to claim 1,
wherein a distance between a fifth end of the third electrode facing the fifth electrode and a sixth end of the fourth electrode facing the sixth electrode is equal to a distance between a seventh end of the fifth electrode facing the third electrode and an eighth end of the sixth electrode facing the fourth electrode.

4. The electronic component according to claim 1,
wherein a length of the first electrode and a length of the second electrode are equal.

5. The electronic component according to claim 1,
wherein a length of the third electrode and the length of the fifth electrode are equal, and
a length of the fourth electrode and a length of the sixth electrode are equal.

6. The electronic component according to claim 1,
wherein each of the first electrodes, each of the second electrodes, each of the third electrodes, each of the fourth electrodes, each of the fifth electrodes and each of the sixth electrodes are provided in each of the first through holes.

7. The electronic component according to claim 1,
wherein the first substrate includes Si (silicon), and
the first electrodes, the second electrodes, the third electrodes, the fourth electrodes, the fifth electrodes, and the sixth electrodes include metal nitride or W (tungsten).

8. The electronic component according to claim 6, further comprising:
an insulating film provided between the first substrate and the first electrodes, the second electrodes, the third electrodes, the fourth electrodes, the fifth electrodes and the sixth electrodes.

9. The electronic component according to claim 8,
wherein the insulating film includes silicon oxide.

10. The electronic component according to claim 8,
wherein the first substrate is a semiconductor substrate, and
each of the side surfaces of the first through holes include an exposed portion in the vicinity of the second substrate surface.

11. The electronic component according to claim 10,
wherein the first substrate further includes a plurality of concavities on each of the side surfaces between the insulating film and the second substrate surface, and each of the concavities surrounding each of the first through holes.

12. The electronic component according to claim 6, further comprising:
a plurality of first junction electrodes provided on the first substrate surface, and each of the first junction electrodes being electrically connected to each of the first electrodes;
a plurality of second junction electrodes provided on the first substrate surface, and each of the second junction electrodes being electrically connected to each of the second electrodes;
a second substrate including a plurality of second through holes and a third substrate surface facing the first substrate surface;
a plurality of third junction electrodes provided on the third substrate surface, each of the third junction electrodes being electrically connected to each of the first junction electrodes; and
a plurality of fourth junction electrodes provided on the third substrate surface, each of the fourth junction electrodes being electrically connected to each of the second junction electrodes.

13. The electronic component according to claim 12,
wherein the first junction electrodes, the second junction electrodes, the third junction electrodes, and the fourth junction electrodes include Au (gold) or Cu (copper).

14. A charged particle beam irradiation apparatus comprising the electronic component according to claim 1.
